(19) United States
(12) Patent Application Publication
(10) Pub. No.: US 2026/0173371 A1
(43) Pub. Date: Jun. 18, 2026

(54) THREE-DIMENSIONAL MEMORY DEVICE INCLUDING CAVITY-CONTAINING DIELECTRIC PILLAR STRUCTURES AND METHODS FOR FORMING THE SAME

(71) Applicant: Sandisk Technologies, Inc., Milpitas, CA (US)

(72) Inventors: Atsushi SHIMIZU, Yokkaichi (JP); Hikaru IOKA, Yokkaichi (JP)

(21) Appl. No.: 18/980,538

(22) Filed: Dec. 13, 2024

(51) Int. Cl. H10B 43/27; H10B 43/10

(52) U.S. Cl. CPC H10B 43/27; H10B 43/10

(57) ABSTRACT

A semiconductor structure includes alternating stacks of insulating layers and electrically conductive layers, where each of the alternating stacks laterally extends along a first horizontal direction, and the alternating stacks are laterally spaced apart from each other along a second horizontal direction by lateral isolation trenches that laterally extend along the first horizontal direction, memory openings vertically extending through a respective one of the alternating stacks; and memory opening fill structures located in a respective one of the memory openings and including a vertical semiconductor channel and respective vertical stack of memory elements located at levels of the electrically conductive layers. Each of the lateral isolation trenches includes a laterally alternating sequence of uniform width regions and laterally-bulging portions that are interlaced along the first horizontal direction, and each of the laterally-bulging portions is filled with a respective cavity-containing dielectric pillar structure containing at least one encapsulated cavity therein.

### FIELD

The present disclosure relates generally to the field of semiconductor devices, and particularly to a three-dimensional memory device including cavity-containing dielectric pillar structures and methods of forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure includes alternating stacks of insulating layers and electrically conductive layers, where each of the alternating stacks laterally extends along a first horizontal direction, and the alternating stacks are laterally spaced apart from each other along a second horizontal direction by lateral isolation trenches that laterally extend along the first horizontal direction, memory openings vertically extending through a respective one of the alternating stacks; and memory opening fill structures located in a respective one of the memory openings and including a vertical semiconductor channel and respective vertical stack of memory elements located at levels of the electrically conductive layers. Each of the lateral isolation trenches includes a laterally alternating sequence of uniform width regions and laterally-bulging portions that are interlaced along the first horizontal direction, and each of the laterally-bulging portions is filled with a respective cavity-containing dielectric pillar structure containing at least one encapsulated cavity comprising an air gap therein.

According to another aspect of the present disclosure, a method of forming a semiconductor structure comprises forming at least one vertically alternating sequence of continuous insulating layers and continuous sacrificial material layers; forming lateral isolation trenches and isolation openings though the at least one vertically alternating sequence; forming sets of isolation-region sacrificial fill material portions in the at least one vertically alternating sequence, wherein each set of isolation-region sacrificial fill material portions comprises a laterally alternating sequence of sacrificial wall structures formed in the lateral isolation trenches, and sacrificial isolation opening fill structures formed in the isolation openings that alternate along a first horizontal direction; forming memory openings through the at least one vertically alternating sequence; forming memory opening fill structures in the memory openings, wherein each of the memory opening fill structures comprises a respective vertical semiconductor channel and a respective vertical stack of memory elements; removing the sacrificial isolation opening fill structures to reopen the isolation openings; laterally-expanding the isolation openings by isotropically recessing proximal portions of the continuous sacrificial material layers and proximal portions of the continuous insulating layers, such that combination of the laterally-expanded isolation openings and the sacrificial wall structures divide the at least one vertically alternating sequence into alternating stacks of insulating layers and sacrificial material layers that are laterally spaced apart from each other along a second horizontal direction; depositing a dielectric fill material at least in a peripheral portion of the laterally-expanded isolation openings; and replacing the sacrificial material layers with electrically conductive layers.

### BRIEF DESCRIPTION OF THE DRAWINGS

FIG. 1A is vertical cross-sectional view of an exemplary structure after formation of optional semiconductor devices, optional lower level dielectric layers, optional lower metal interconnect structures, a semiconductor material layer, and a first-tier vertically alternating sequence of first continuous insulating layers and first continuous sacrificial material layers, a first insulating cap layer, first stepped surfaces, first retro-stepped dielectric material portions, and sacrificial first-tier fill structures according to an embodiment of the present disclosure. FIG. 1B is a top-down view of the exemplary structure of FIG. 1A. The vertical plane A-A′ in FIG. 1B is the cut plane of the vertical cross-sectional view of FIG. 1A. FIG. 1C is a vertical cross-sectional view of the exemplary structure along the hinged vertical cut plane C-C′ in FIG. 1B.

FIG. 2A is vertical cross-sectional view of the exemplary structure after formation of a second-tier vertically alternating sequence of second continuous insulating layers and second continuous sacrificial material layers, a second insulating cap layer, second stepped surfaces, second retro-stepped dielectric material portions, and sacrificial second-tier fill structures according to an embodiment of the present disclosure. FIG. 2B is a top-down view of the exemplary structure of FIG. 2A. The vertical plane A-A′ in FIG. 2B is the cut plane of the vertical cross-sectional view of FIG. 2A. FIG. 2C is a vertical cross-sectional view of the exemplary structure along the hinged vertical cut plane C-C′ in FIG. 2B.

FIG. 3A is vertical cross-sectional view of the exemplary structure after formation of a third-tier vertically alternating sequence of third continuous insulating layers and third continuous sacrificial material layers, a third insulating cap layer, third stepped surfaces, third retro-stepped dielectric material portions, and sacrificial third-tier fill structures according to an embodiment of the present disclosure. FIG. 3B is a top-down view of the exemplary structure of FIG. 3A. The vertical plane A-A′ in FIG. 3B is the cut plane of the vertical cross-sectional view of FIG. 3A. FIG. 3C is a vertical cross-sectional view of the exemplary structure along the hinged vertical cut plane C-C′ in FIG. 3B.

FIG. 4 is a vertical cross-sectional view of the exemplary structure after formation of inter-tier memory openings and inter-tier support openings according to an embodiment of the present disclosure.

FIGS. 5A-D illustrate sequential vertical cross-sectional views of a memory opening during formation of a memory opening fill structure according to an embodiment of the present disclosure.

FIG. 6A is vertical cross-sectional view of the exemplary structure after formation of memory opening fill structures according to an embodiment of the present disclosure. FIG. 6B is a top-down view of the exemplary structure of FIG. 6A. The vertical plane A-A′ in FIG. 6B is the cut plane of the vertical cross-sectional view of FIG. 6A. FIG. 6C is a vertical cross-sectional view of the exemplary structure along the hinged vertical cut plane C-C′ in FIG. 6B.

FIG. 7 is a vertical cross-sectional view of the exemplary structure after formation of a contact-level dielectric layer and a patterned photoresist layer including openings over areas of sacrificial isolation opening fill structures according to an embodiment of the present disclosure.

FIG. 8 is a vertical cross-sectional view of the exemplary structure after formation of discrete openings through the contact-level dielectric layer according to an embodiment of the present disclosure.

FIG. 9 is a vertical cross-sectional view of the exemplary structure after removal of the sacrificial isolation opening fill structures according to an embodiment of the present disclosure.

FIG. 10A is a vertical cross-sectional view of the exemplary structure after performing a first isotropic etch process according to an embodiment of the present disclosure. FIG. 10B is a top-down view of the exemplary structure of FIG. 10A. The hinged vertical cut plane A-A′ is the plane of the vertical cross-sectional view of FIG. 10A.

FIG. 11A is a vertical cross-sectional view of the exemplary structure after performing a second isotropic etch process according to an embodiment of the present disclosure. FIG. 11B is a top-down view of the exemplary structure of FIG. 11A. The hinged vertical cut plane A-A′ is the plane of the vertical cross-sectional view of FIG. 11A.

FIG. 12 is a vertical cross-sectional view of the exemplary structure after performing a surface oxidation process according to an embodiment of the present disclosure.

FIG. 13 is a vertical cross-sectional view of the exemplary structure after formation of additional openings over the areas of sacrificial support opening fill structures according to an embodiment of the present disclosure.

FIG. 14 is a vertical cross-sectional view of the exemplary structure after removal of the sacrificial support opening fill structures according to an embodiment of the present disclosure.

FIG. 15A is a vertical cross-sectional view of the exemplary structure after formation of cavity-containing dielectric pillar structures and dielectric support pillars according to an embodiment of the present disclosure. FIG. 15B is a top-down view of the exemplary structure of FIG. 15A. The hinged vertical cut plane A-A′ is the plane of the vertical cross-sectional view of FIG. 15A.

FIG. 16 is a vertical cross-sectional view of the exemplary structure after removal of sacrificial contact opening fill structures according to an embodiment of the present disclosure.

FIG. 17 is a vertical cross-sectional view of the exemplary structure after formation of finned contact via cavities according to an embodiment of the present disclosure.

FIG. 18 is a vertical cross-sectional view of the exemplary structure after formation of annular dielectric isolation fins according to an embodiment of the present disclosure.

FIG. 19 is a vertical cross-sectional view of the exemplary structure after formation of sacrificial contact via structures according to an embodiment of the present disclosure.

FIG. 20A is a vertical cross-sectional view of the exemplary structure after formation of openings over sacrificial wall structures according to an embodiment of the present disclosure. FIG. 20B is a top-down view of the exemplary structure of FIG. 20A. The hinged vertical cut plane A-A′ is the plane of the vertical cross-sectional view of FIG. 20A.

FIG. 21 is a vertical cross-sectional view of the exemplary structure after removal of the sacrificial wall structures according to an embodiment of the present disclosure.

FIG. 22 is a vertical cross-sectional view of the exemplary structure after formation of laterally-extending cavities according to an embodiment of the present disclosure.

FIG. 23 is a vertical cross-sectional view of the exemplary structure after formation of electrically conductive layers according to an embodiment of the present disclosure.

FIGS. 24A and 24B are vertical cross-sectional views of alternative exemplary structures after filling of the lateral isolation trenches according to alternative embodiments of the present disclosure.

FIG. 25 is a vertical cross-sectional view of the exemplary structure after removal of the sacrificial contact via structures according to an embodiment of the present disclosure.

FIG. 26A is a vertical cross-sectional view of the exemplary structure after formation of layer contact via structures according to an embodiment of the present disclosure. FIG. 26B is a top-down view of the exemplary structure of FIG. 26A. The hinged vertical cut plane A-A′ is the plane of the vertical cross-sectional view of FIG. 26A.

FIG. 27A is a vertical cross-sectional view of the exemplary structure after formation of drain contact via structures according to an embodiment of the present disclosure. FIG. 27B is a top-down view of the exemplary structure of FIG. 27A. The hinged vertical cut plane A-A′ is the plane of the vertical cross-sectional view of FIG. 27A.

FIG. 28A is a vertical cross-sectional view of an upper portion of the inter-array region of the exemplary structure along hinged vertical cut plane A-A′ in FIG. 28B. FIG. 28B is a horizontal cross-sectional view of the upper portion of the inter-array region of the exemplary structure along horizontal plane B-B′ in FIG. 28A. FIG. 28C is a vertical cross-sectional view of an upper portion of the inter-array region of the exemplary structure along vertical cut plane C-C′ in FIG. 28B. FIG. 28D is a cut-away perspective view of the upper portion of the inter-array region shown in FIG. 28A.

FIG. 29A is a vertical cross-sectional view of a lower portion of the inter-array region of the exemplary structure along hinged vertical cut plane A-A′ in FIG. 28B. FIG. 29B is a vertical cross-sectional view of the lower portion of the inter-array region of the exemplary structure along vertical cut plane C-C′ in FIG. 28B. FIG. 29C is a cut-away perspective view of the lower portion of the inter-array region shown in FIG. 29A.

### DETAILED DESCRIPTION

As discussed above, the embodiments of the present disclosure are directed to a three-dimensional memory device including cavity-containing dielectric pillar structures and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

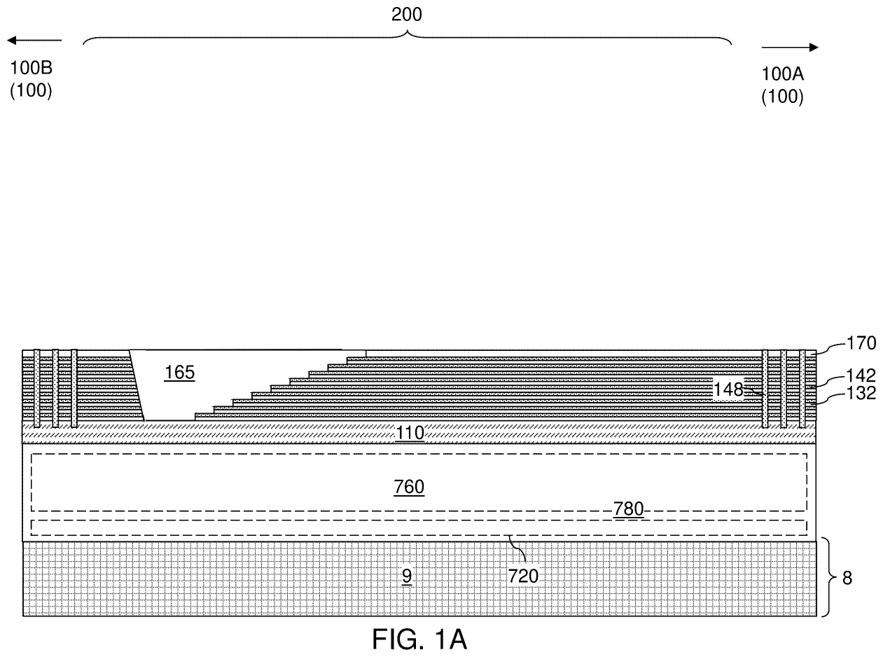

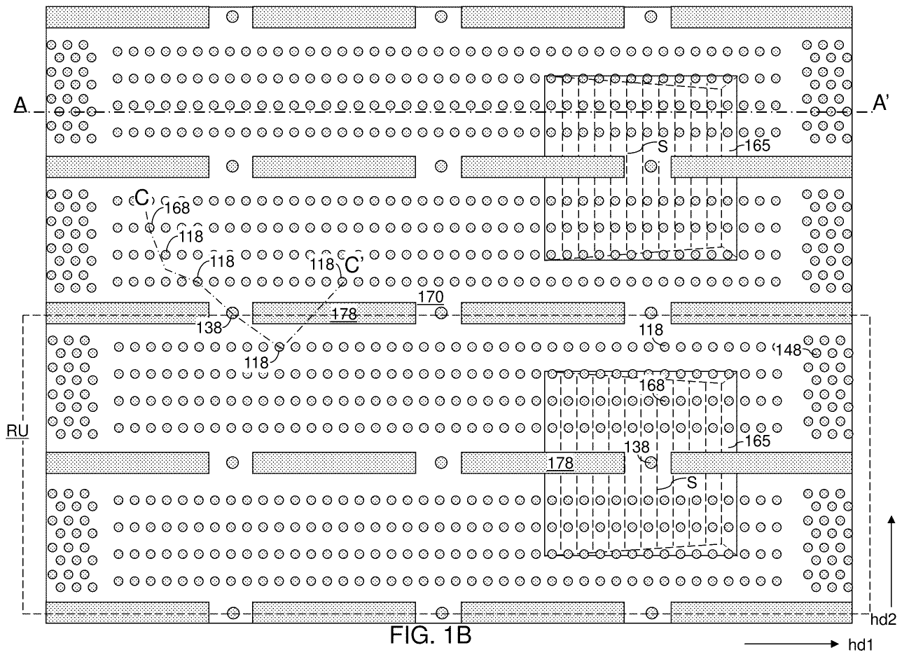

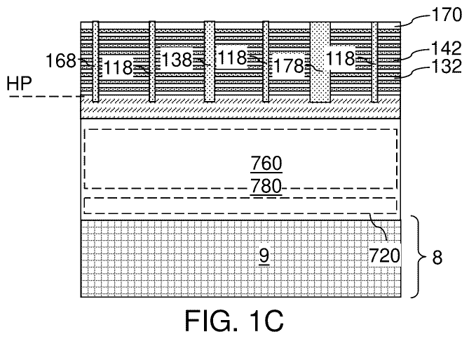

Referring to FIGS. 1A-1C, an exemplary structure according to an embodiment of the present disclosure is illustrated after formation of optional semiconductor devices, optional lower level dielectric layers, optional lower metal interconnect structures, a semiconductor material layer 110, and a first-tier vertically alternating sequence (132, 142) of first continuous insulating layers 132 and first continuous sacrificial material layers 142, a first insulating cap layer 170, first stepped surfaces, first retro-stepped dielectric material portions 165, and sacrificial first-tier fill structures (148, 118, 138, 168) according to an embodiment of the present disclosure.

The exemplary structure comprises a substrate 8 (e.g., silicon wafer or another substrate) including a substrate semiconductor layer 9 (e.g., doped well in the silicon wafer or a silicon layer located on the substrate 8). Semiconductor devices 720 can be formed on the substrate semiconductor layer 9. In one embodiment, the semiconductor devices 720 may comprise a peripheral circuit configured to control operation of a three-dimensional memory device to be subsequently formed. Lower-level dielectric material layer 760 embedding lower-level metal interconnect structures 780 (not individually shown) may be formed over the semiconductor devices 720. In some embodiments, the lower-level metal interconnect structures 780 may comprise metal pads 788 configured to be subsequently connected to connection via structures and electrically connected to a respective node of the semiconductor devices 720 through a subset of the lower-level metal interconnect structures 780.

In an alternative embodiment, the peripheral circuit containing the semiconductor devices 720 may be formed on a separate substrate that is part of a logic die. The logic may be subsequently bonded to a memory die containing a three-dimensional memory device formed over the substrate 8.

A semiconductor material layer 110 can be formed over the lower-level dielectric material layers 760 by deposition of a semiconductor material or by transfer of the semiconductor material layer 110 employing a carrier substrate (not shown). The semiconductor material layer 110 may comprise a polycrystalline semiconductor material layer or a single crystalline semiconductor material layer. The thickness of the semiconductor material layer 110 may be in a range from 100 nm to 2,000 nm, although lesser and greater thicknesses may also be employed. A top surface of the semiconductor material layer 110 may be provided within a horizontal plane HP.

A first-tier vertically alternating sequence of first insulating layers 132 and first sacrificial material layers 142 can be formed over the semiconductor material layer 110. Each of the first insulating layers 132 may be formed as single continuous material layer, and thus, may be referred to as a first continuous insulating layer. Each of the first sacrificial material layers 142 may be formed as a single continuous material layer, and thus, may be formed as a first continuous sacrificial material layer. Each of the first insulating layers 132 and the first sacrificial material layers 142 may have a thickness in a range from 20 nm to 80 nm, although lesser and greater thicknesses may also be employed. In one embodiment, the first-tier vertically alternating sequence of first insulating layers 132 and first sacrificial material layers 142 may include a periodic repetition of a unit layer stack including a first insulating layer 132 and a first sacrificial material layer 142. The total number of repetitions of the unit layer stack may be in a range from 4 to 1,024, such as from 16 to 256, although lesser and greater numbers of repetition may also be employed. The first insulating layers 132 may comprise, and/or may consist essentially of, an insulating material such as undoped silicate glass or a doped silicate glass. The first sacrificial material layers 142 may comprise, and/or may consist essentially of, a sacrificial material such as silicon nitride, a silicon-germanium alloy, organosilicate glass, or a polymer material. Generally, the first sacrificial material layers 142 comprise a material that may be removed selectively to the materials of the first insulating layers 132 and the semiconductor material layer 110.

A first insulating cap layer 170 can be formed over the first-tier vertically alternating sequence of first insulating layers 132 and first sacrificial material layers 142. According to an aspect of the present disclosure, the first insulating cap layer 170 may comprise a same material as the first insulating layers 132, and is thicker than the first insulating layers 132. For example, the first insulating cap layer 170 may have a thickness in a range from 150% to 1,000% of the thickness of the first insulating layers 132.

A first patterned hard mask layer (not shown) may be formed over the first-tier vertically alternating sequence (132, 142) to define areas in which first stepped surfaces are to be subsequently formed. A first trimmable etch mask layer (not shown) can be formed over the first patterned hard mask layer, and can be lithographically patterned to form slit-shaped openings over peripheral regions of the openings in the first patterned hard mask layer. A unit processing sequence can be repeated performed to form first stepped surfaces in the first-tier vertically alternating sequence (132, 142) within the areas of openings in the first patterned hard mask layer. For example, the unit processing sequence may comprise an anisotropic etch process that etches a pair of a first insulating layer 132 and a first sacrificial material layer 142 and a trimming process that isotropically trims the first trimmable etch mask layer. The number of repetitions of the unit processing sequence may be the same as the total number of first sacrificial material layers 142 in the first-tier vertically alternating sequence (132, 142). A first stepped cavity overlying a respective set of first stepped surfaces of the first-tier vertically alternating sequence (132, 142) can be formed within each patterned area of the first-tier vertically alternating sequence (132, 142).

In one embodiment, the vertical steps within each first stepped cavity may be laterally spaced from each other along a first horizontal direction hd1 (which may be a word line direction). In one embodiment, the first stepped cavities may be arranged along a second horizontal direction hd2 (which may be a bit line direction). In one embodiment, the exemplary structure may have a periodic pattern that repeats along the first horizontal direction hd1. Specifically, a repetition unit RU is repeated along the second horizontal direction hd2. In one embodiment, each repetition unit RU may comprise a first stepped cavity. Physically exposed portions of the first continuous sacrificial material layers 142 can be locally thickened underneath the first stepped cavities by depositing and patterning additional sacrificial material thereon.

In one embodiment, the lateral extent of the layers of the first alternating sequence (132, 142) along a first horizontal direction hd1 may vary (e.g., decrease) with a vertical distance from the substrate 8 within each region including a respective set of first stepped surfaces. In one embodiment, each opening in the topmost layer of the first-tier vertically alternating sequence (132, 142) may have a rectangular shape having a pair of lengthwise sides laterally extending along the first horizontal direction hd1 and a pair of widthwise sides laterally extending along a second horizontal direction hd2 that is perpendicular to the first horizontal direction hd1. Each set of first stepped surfaces may comprise vertical steps S shown in FIG. 1B. Tapered surfaces may be formed around each first stepped cavity between the stepped surfaces and the topmost horizontal surface of the first-tier vertically alternating sequence (132, 142). Alternative schemes employing repetition of an etch step and a trimming step may be employed to pattern portions of the first-tier vertically alternating sequence (132, 142) that are not masked by the first patterned hard mask layer. The first trimmable etch mask layer and the first patterned hard mask layer can be subsequently removed.

A dielectric fill material can be deposited within each of the first stepped cavities to form first retro-stepped dielectric material portions 165. A first-tier structure is formed, which comprises the first-tier vertically alternating sequence (132, 142), the first retro-stepped dielectric material portions 165, and the first insulating cap layer 170.

Various first-tier openings can be formed through the first-tier structure (132, 142, 165, 170) and into an upper portion of the semiconductor material layer 110. A photoresist layer (not shown) can be applied over the first insulating cap layer 170, and can be lithographically patterned to form various openings therethrough. The pattern of openings in the photoresist layer can be transferred through the first-tier structure (132, 142, 165, 170) and into an upper portion of the semiconductor material layer 110 by a first anisotropic etch process to form the various first-tier openings concurrently. The various first-tier openings can include first-tier memory openings, first-tier support openings, sacrificial first-tier contact openings, and first-tier isolation-region openings. The first-tier isolation-region openings may comprise first-tier isolation trenches having a respective rectangular shape and elongated along the first horizontal direction, and first-tier isolation openings having a respective circular or elliptical shape.

The first-tier memory openings are formed in the memory array regions 100 through each layer within the first-tier vertically alternating sequence (132, 142). The first-tier memory openings are subsequently employed to form memory stack structures therein. The first-tier memory openings can be formed in clusters that are laterally spaced apart along the second horizontal direction hd2. Each cluster of first-tier memory openings can be formed as a two-dimensional array of first-tier memory openings.

The first-tier isolation trenches may be formed as a two-dimensional array of first-tier isolation trenches having a regular periodicity. The two-dimensional arrays of first-tier isolation trenches may comprise rows of first-tier isolation trenches. Each row of first-tier isolation trenches can be arranged along the first horizontal direction hd1. Each first-tier isolation trench may laterally extend along the first horizontal direction hd1 with a uniform width along the second horizontal direction hd2. The first-tier isolation trenches within each row of first-tier isolation trenches may be laterally spaced from each other along the first horizontal direction hd1 by a spacing that exceeds a lateral dimension of each first-tier isolation opening.

The first-tier isolation openings may be formed as a two-dimensional array of first-tier isolation openings having the same periodicity as the first-tier isolation trenches. The two-dimensional arrays of first-tier isolation openings may comprise rows of first-tier isolation openings. Each row of first-tier isolation openings can be arranged along the first horizontal direction hd1. A two-dimensional array of first-tier isolation openings may be interlaced with the two-dimensional array of first-tier isolation trenches such that a first-tier isolation opening is provided between each neighboring pair of first-tier isolation trenches that are laterally spaced from each other along the first horizontal direction hd1.

The combination of the first-tier isolation trenches and the first-tier isolation openings laterally extends between neighboring clusters of first-tier memory openings. Each laterally alternating sequence of first-tier isolation trenches and the first-tier isolation openings may laterally extend through the first memory array region 100A, the inter-array region 200, and the second memory array region 100B. Laterally alternating sequences of a first type comprise respective first-tier isolation trenches and respective first-tier isolation openings, and extend between neighboring pairs of first retro-stepped dielectric material portions 165. Laterally alternating sequences of a second type comprise respective first-tier isolation trenches and respective first-tier isolation openings, and extend through a respective first retro-stepped dielectric material portion 165. Each repetition unit RU may comprise a first retro-stepped dielectric material portion 165, a laterally alternating sequence of a first type, and a laterally alternating sequence of a second type.

The sacrificial first-tier contact openings can be formed through the first retro-stepped dielectric material portions 165 through a respective horizontally-extending surface segment of the first stepped surfaces.

The first-tier support openings can be formed in the inter-array region 200 in areas that are not filled with the sacrificial first-tier contact openings and the first-tier isolation-region openings (i.e., the first-tier isolation openings and the first-tier isolation trenches).

A sacrificial fill material can be deposited in the various first-tier openings to form various sacrificial first-tier opening fill structures. The various sacrificial first-tier opening fill structures comprise sacrificial first-tier memory opening fill structures 148 that are formed in the first-tier memory openings, sacrificial first-tier support opening fill structures 118 that are formed in the first-tier support openings, sacrificial first-tier contact opening fill structures 168 that are formed in the sacrificial first-tier contact openings, sacrificial first-tier isolation opening fill structures 138 that are formed in the first-tier isolation openings, and sacrificial first-tier wall structures 178 that are formed in the first-tier isolation trenches. The sacrificial fill material in the various sacrificial first-tier opening fill structures comprises a material that is different from the materials of the first insulating layers 132 and the first sacrificial material layers 142. For example, the sacrificial fill material in the various sacrificial first-tier opening fill structures may comprise a semiconductor material (such as amorphous silicon or silicon-germanium).

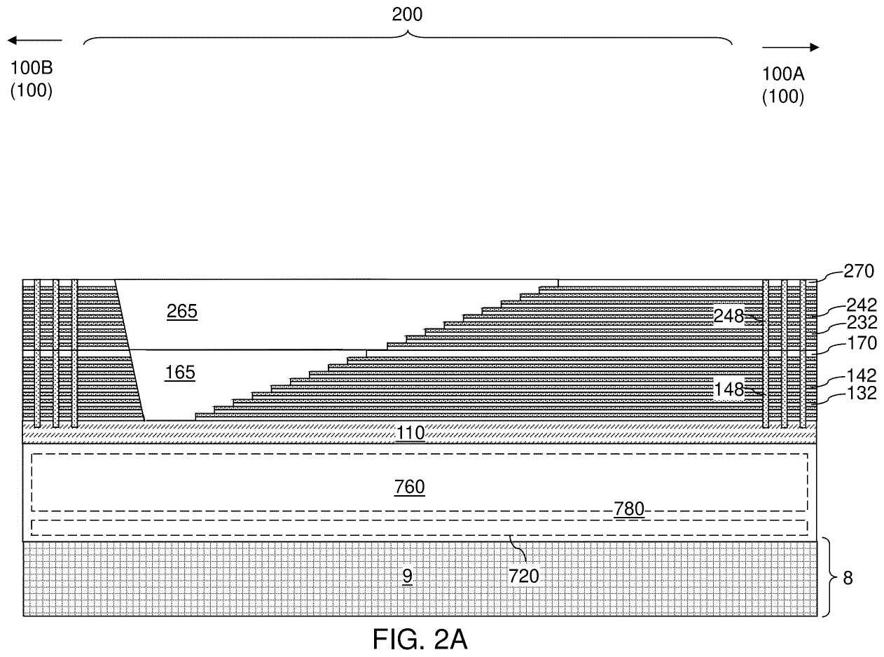

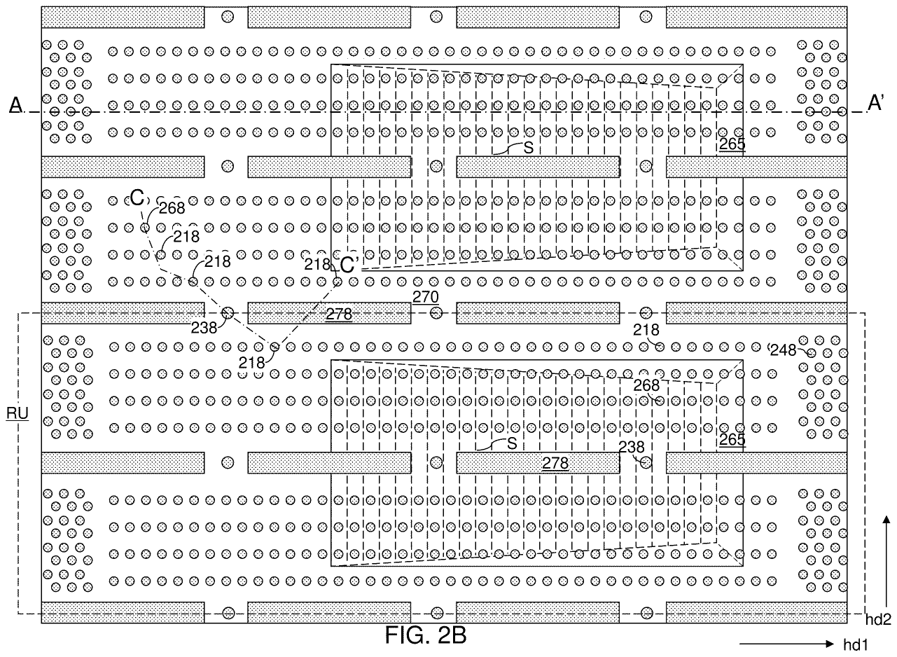

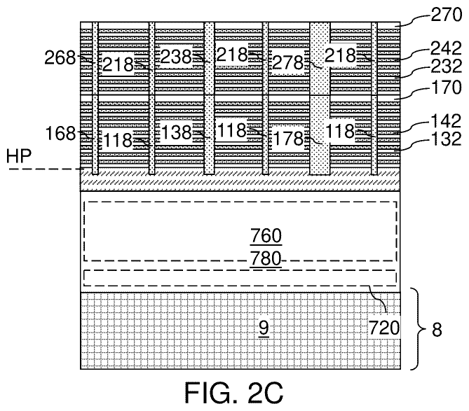

Referring to FIGS. 2A-2C, a second-tier vertically alternating sequence of second insulating layers 232 and second sacrificial material layers 242 can be formed over the first-tier structure. Each of the second insulating layers 232 may be formed as single continuous material layer, and thus, may be referred to as a second continuous insulating layer. Each of the second sacrificial material layers 242 may be formed as a single continuous material layer, and thus, may be formed as a second continuous sacrificial material layer. Each of the second insulating layers 232 and the second sacrificial material layers 242 may have a thickness in a range from 20 nm to 80 nm, although lesser and greater thicknesses may also be employed. In one embodiment, the first-tier vertically alternating sequence of second insulating layers 232 and second sacrificial material layers 242 may include a periodic repetition of a unit layer stack including a second insulating layer 232 and a second sacrificial material layer 242. The total number of repetitions of the unit layer stack may be in a range from 4 to 1,024, such as from 16 to 256, although lesser and greater numbers of repetition may also be employed. The second insulating layers 232 may comprise, and/or may consist essentially of, an insulating material such as undoped silicate glass or a doped silicate glass. The second sacrificial material layers 242 may comprise, and/or may consist essentially of, a sacrificial material such as silicon nitride, a silicon-germanium alloy, organosilicate glass, or a polymer material. Generally, the second sacrificial material layers 242 comprise a material that may be removed selectively to the materials of the second insulating layers 232 and the semiconductor material layer 110. The second insulating layers 232 may comprise the same material as the first insulating layers 132, and the second sacrificial material layers 242 may comprise the same material as the first sacrificial material layers 142.

A second insulating cap layer 270 can be formed over the first-tier vertically alternating sequence of second insulating layers 232 and second sacrificial material layers 242. According to an aspect of the present disclosure, the second insulating cap layer 270 may comprise a same material as the second insulating layers 232, and is thicker than the second insulating layers 232. For example, the second insulating cap layer 270 may have a thickness in a range from 150% to 1,000% of the thickness of the second insulating layers 232.

A second patterned hard mask layer (not shown) may be formed over the first-tier vertically alternating sequence (232, 242) to define areas in which second stepped surfaces are to be subsequently formed. A second trimmable etch mask layer (not shown) can be formed over the second patterned hard mask layer, and can be lithographically patterned to form slit-shaped openings over peripheral regions of the openings in the second patterned hard mask layer. A unit processing sequence can be repeated performed to form second stepped surfaces in the first-tier vertically alternating sequence (232, 242) within the areas of openings in the second patterned hard mask layer. For example, the unit processing sequence may comprise an anisotropic etch process that etches a pair of a second insulating layer 232 and a second sacrificial material layer 242 and a trimming process that isotropically trims the second trimmable etch mask layer. The number of repetitions of the unit processing sequence may be the same as the total number of second sacrificial material layers 242 in the first-tier vertically alternating sequence (232, 242). A second stepped cavity overlying a respective set of second stepped surfaces of the first-tier vertically alternating sequence (232, 242) can be formed within each patterned area of the first-tier vertically alternating sequence (232, 242).

In one embodiment, the vertical steps within each second stepped cavity may be laterally spaced from each other along the first horizontal direction hd1 (which may be the word line direction). In one embodiment, the second stepped cavities may be arranged along a second horizontal direction hd2 (which may be a bit line direction). In one embodiment, the exemplary structure may have a periodic pattern that repeats along the first horizontal direction hd1. Specifically, a pattern in a repetition unit RU is repeated along the second horizontal direction hd2. In one embodiment, each repetition unit RU may comprise a second stepped cavity. Physically exposed portions of the second continuous sacrificial material layers 242 can be locally thickened underneath the second stepped cavities.

In one embodiment, the lateral extent of the layers of the second alternating sequence (232, 242) along a first horizontal direction hd1 may vary (e.g., decrease) with a vertical distance from the substrate 8 within each region including a respective set of second stepped surfaces. In one embodiment, each opening in the topmost layer of the first-tier vertically alternating sequence (232, 242) may have a rectangular shape having a pair of lengthwise sides laterally extending along the first horizontal direction hd1 and a pair of widthwise sides laterally extending along a second horizontal direction hd2 that is perpendicular to the first horizontal direction hd1. Each set of second stepped surfaces may comprise vertical steps S. Tapered surfaces may be formed around each second stepped cavity between the stepped surfaces and the topmost horizontal surface of the first-tier vertically alternating sequence (232, 242). Alternative schemes employing repetition of an etch step and a trimming step may be employed to pattern portions of the first-tier vertically alternating sequence (232, 242) that are not masked by the second patterned hard mask layer. The second trimmable etch mask layer and the second patterned hard mask layer can be subsequently removed.

A dielectric fill material can be deposited within each of the second stepped cavities to form second retro-stepped dielectric material portions 265. A second-tier structure is formed, which comprises the first-tier vertically alternating sequence (232, 242), the second retro-stepped dielectric material portions 265, and the second insulating cap layer 270.

Various second-tier openings can be formed through the second-tier structure (232, 242, 265, 270). A photoresist layer (not shown) can be applied over the second insulating cap layer 270, and can be lithographically patterned to form various openings therethrough. The pattern of openings in the photoresist layer can be transferred through the second-tier structure (232, 242, 265, 270) by a second anisotropic etch process to form the various second-tier openings concurrently. The various second-tier openings can include second-tier memory openings, second-tier support openings, sacrificial second-tier contact openings, and second-tier isolation-region openings. The second-tier isolation-region openings may comprise second-tier isolation trenches having a respective rectangular shape and elongated along the second horizontal direction, and second-tier isolation openings having a respective circular or elliptical shape.

The second-tier memory openings are formed in the memory array regions 100 through each layer within the first-tier vertically alternating sequence (232, 242) and exposing an underlying structure 148. The second-tier memory openings are subsequently employed to form memory stack structures therein. The second-tier memory openings can be formed in clusters that are laterally spaced apart along the second horizontal direction hd2. Each cluster of second-tier memory openings can be formed as a two-dimensional array of second-tier memory openings.

The second-tier isolation trenches may be formed as a two-dimensional array of second-tier isolation trenches having a rectangular periodicity. The two-dimensional arrays of second-tier isolation trenches may comprise rows of second-tier isolation trenches. Each row of second-tier isolation trenches can be arranged along the first horizontal direction hd1. Each second-tier isolation trench may laterally extend along the first horizontal direction hd1 with a uniform width along the second horizontal direction hd2. The second-tier isolation trenches within each row of second-tier isolation trenches may be laterally spaced from each other along the first horizontal direction hd1 by a spacing that exceeds a lateral dimension of each second-tier isolation opening.

The second-tier isolation openings may be formed as a two-dimensional array of second-tier isolation openings having the same periodicity as the second-tier isolation trenches. The two-dimensional arrays of second-tier isolation openings may comprise rows of second-tier isolation openings. Each row of second-tier isolation openings can be arranged along the first horizontal direction hd1. A two-dimensional array of second-tier isolation openings may be interlaced with the two-dimensional array of second-tier isolation trenches such that a second-tier isolation opening is provided between each neighboring pair of second-tier isolation trenches that are laterally spaced from each other along the first horizontal direction hd1.

The combination of the second-tier isolation trenches and the second-tier isolation openings laterally extends between neighboring clusters of second-tier memory openings. Each laterally alternating sequence of second-tier isolation trenches and the second-tier isolation openings may laterally extend through the second memory array region 100A, the inter-array region 200, and the second memory array region 100B. Laterally alternating sequences of a first type comprise respective second-tier isolation trenches and respective second-tier isolation openings, and extend between neighboring pairs of second retro-stepped dielectric material portions 265. Laterally alternating sequences of a second type comprise respective second-tier isolation trenches and respective second-tier isolation openings, and extend through a respective second retro-stepped dielectric material portion 265. Each repetition unit RU may comprise a second retro-stepped dielectric material portion 265, a laterally alternating sequence of a first type, and a laterally alternating sequence of a second type.

The sacrificial second-tier contact openings can be formed through the second retro-stepped dielectric material portions 265 through a respective horizontally-extending surface segment of the second stepped surfaces.

The second-tier support openings can be formed in the inter-array region 200 in areas that are not filled with the sacrificial second-tier contact openings and the second-tier isolation-region openings (i.e., the second-tier isolation openings and the second-tier isolation trenches).

A sacrificial fill material can be deposited in the various second-tier openings to form various sacrificial second-tier opening fill structures. The various sacrificial second-tier opening fill structures comprise sacrificial second-tier memory opening fill structures 248 that are formed in the second-tier memory openings, sacrificial second-tier support opening fill structures 218 that are formed in the second-tier support openings, sacrificial second-tier contact opening fill structures 268 that are formed in the sacrificial second-tier contact openings, sacrificial second-tier isolation opening fill structures 238 that are formed in the second-tier isolation openings, and sacrificial second-tier wall structures 278 that are formed in the second-tier isolation trenches. The sacrificial fill material in the various sacrificial second-tier opening fill structures comprises a material that is different from the materials of the second insulating layers 232 and the second sacrificial material layers 242. For example, the sacrificial fill material in the various sacrificial second-tier opening fill structures may comprise a semiconductor material (such as amorphous silicon or silicon-germanium).

Each sacrificial second-tier memory opening fill structure 248 may be formed on a top surface of and may have an areal overlap in the plan view with a respective sacrificial first-tier memory opening fill structure 148. Each sacrificial second-tier support opening fill structure 218 may be formed on a top surface of and may have an areal overlap in the plan view with a respective sacrificial first-tier support opening fill structure 118. Each sacrificial second-tier contact opening fill structure 268 may be formed on a top surface of and may have an areal overlap in the plan view with a respective sacrificial first-tier contact opening fill structure 168. Each sacrificial second-tier isolation opening fill structure 238 may be formed on a top surface of and may have an areal overlap in the plan view with a respective sacrificial first-tier isolation opening fill structure 138. Each sacrificial second-tier wall structure 278 may be formed on a top surface of and may have an areal overlap in the plan view with a respective sacrificial first-tier wall structure 178.

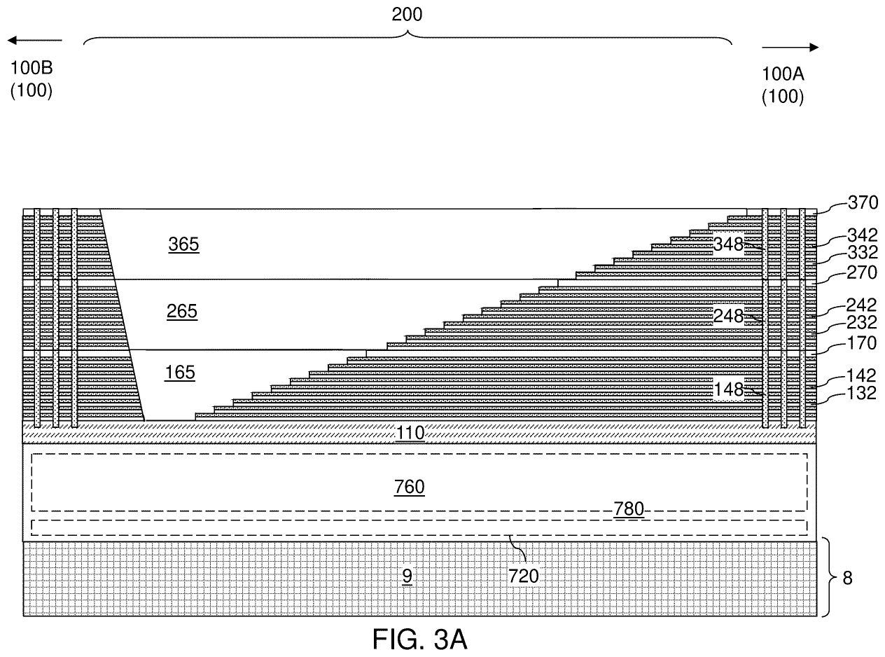

Referring to FIGS. 3A-3C, a third-tier vertically alternating sequence of third insulating layers 332 and third sacrificial material layers 342 can be formed over the semiconductor material layer 110. Each of the third insulating layers 332 may be formed as single continuous material layer, and thus, may be referred to as a third continuous insulating layer. Each of the third sacrificial material layers 342 may be formed as a single continuous material layer, and thus, may be formed as a third continuous sacrificial material layer. Each of the third insulating layers 332 and the third sacrificial material layers 342 may have a thickness in a range from 20 nm to 80 nm, although lesser and greater thicknesses may also be employed. In one embodiment, the first-tier vertically alternating sequence of third insulating layers 332 and third sacrificial material layers 342 may include a periodic repetition of a unit layer stack including a third insulating layer 332 and a third sacrificial material layer 342. The total number of repetitions of the unit layer stack may be in a range from 4 to 1,024, such as from 16 to 256, although lesser and greater numbers of repetition may also be employed. The third insulating layers 332 may comprise, and/or may consist essentially of, an insulating material such as undoped silicate glass or a doped silicate glass. The third sacrificial material layers 342 may comprise, and/or may consist essentially of, a sacrificial material such as silicon nitride, a silicon-germanium alloy, organosilicate glass, or a polymer material. Generally, the third sacrificial material layers 342 comprise a material that may be removed selectively to the materials of the third insulating layers 332 and the semiconductor material layer 110. The third insulating layers 332 may comprise the same material as the first insulating layers 132 and the second insulating layers 232, and the second sacrificial material layers 242 may comprise the same material as the first sacrificial material layers 142 and the second sacrificial material layers 242.

A third insulating cap layer 370 can be formed over the first-tier vertically alternating sequence of third insulating layers 332 and third sacrificial material layers 342. According to an aspect of the present disclosure, the third insulating cap layer 370 may comprise a same material as the third insulating layers 332, and is thicker than the third insulating layers 332. For example, the third insulating cap layer 370 may have a thickness in a range from 150% to 1,000% of the thickness of the third insulating layers 332.

A third patterned hard mask layer (not shown) may be formed over the first-tier vertically alternating sequence (332, 342) to define areas in which third stepped surfaces are to be subsequently formed. A third trimmable etch mask layer (not shown) can be formed over the third patterned hard mask layer, and can be lithographically patterned to form slit-shaped openings over peripheral regions of the openings in the third patterned hard mask layer. A unit processing sequence can be repeated performed to form third stepped surfaces in the first-tier vertically alternating sequence (332, 342) within the areas of openings in the third patterned hard mask layer. For example, the unit processing sequence may comprise an anisotropic etch process that etches a pair of a third insulating layer 332 and a third sacrificial material layer 342 and a trimming process that isotropically trims the third trimmable etch mask layer. The number of repetitions of the unit processing sequence may be the same as the total number of third sacrificial material layers 342 in the first-tier vertically alternating sequence (332, 342). A third stepped cavity overlying a respective set of third stepped surfaces of the first-tier vertically alternating sequence (332, 342) can be formed within each patterned area of the first-tier vertically alternating sequence (332, 342).

In one embodiment, the vertical steps within each third stepped cavity may be laterally spaced from each other along a first horizontal direction hd1 (which may be a word line direction). In one embodiment, the third stepped cavities may be arranged along a second horizontal direction hd2 (which may be a bit line direction). In one embodiment, the exemplary structure may have a periodic pattern that repeats along the first horizontal direction hd1. Specifically, a repetition unit RU is repeated along the second horizontal direction hd2. In one embodiment, each repetition unit RU may comprise a third stepped cavity. Physically exposed portions of the third continuous sacrificial material layers 342 can be locally thickened underneath the third stepped cavities.

In one embodiment, the lateral extent of the layers of the third alternating sequence (332, 342) along a first horizontal direction hd1 may vary (e.g., decrease) with a vertical distance from the substrate 8 within each region including a respective set of third stepped surfaces. In one embodiment, each opening in the topmost layer of the first-tier vertically alternating sequence (332, 342) may have a rectangular shape having a pair of lengthwise sides laterally extending along the first horizontal direction hd1 and a pair of widthwise sides laterally extending along a second horizontal direction hd2 that is perpendicular to the first horizontal direction hd1. Each set of third stepped surfaces may comprise vertical steps S, as shown in FIG. 3B. Tapered surfaces may be formed around each third stepped cavity between the stepped surfaces and the topmost horizontal surface of the first-tier vertically alternating sequence (332, 342). Alternative schemes employing repetition of an etch step and a trimming step may be employed to pattern portions of the first-tier vertically alternating sequence (332, 342) that are not masked by the third patterned hard mask layer. The third trimmable etch mask layer and the third patterned hard mask layer can be subsequently removed.

A dielectric fill material can be deposited within each of the third stepped cavities to form third retro-stepped dielectric material portions 365. A third-tier structure is formed, which comprises the first-tier vertically alternating sequence (332, 342), the third retro-stepped dielectric material portions 365, and the third insulating cap layer 370.

Various third-tier openings can be formed through the third-tier structure (332, 342, 365, 370). A photoresist layer (not shown) can be applied over the third insulating cap layer 370, and can be lithographically patterned to form various openings therethrough. The pattern of openings in the photoresist layer can be transferred through the third-tier structure (332, 342, 365, 370) by a third anisotropic etch process to form the various third-tier openings concurrently. The various third-tier openings can include third-tier memory openings, third-tier support openings, sacrificial third-tier contact openings, and third-tier isolation-region openings. The third-tier isolation-region openings may comprise third-tier isolation trenches having a respective rectangular shape and elongated along the third horizontal direction, and third-tier isolation openings having a respective circular or elliptical shape.

The third-tier memory openings are formed in the memory array regions 300 through each layer within the first-tier vertically alternating sequence (332, 342). The third-tier memory openings are subsequently employed to form memory stack structures therein. The third-tier memory openings can be formed in clusters that are laterally spaced apart along the second horizontal direction hd2. Each cluster of third-tier memory openings can be formed as a two-dimensional array of third-tier memory openings.

The third-tier isolation trenches may be formed as a two-dimensional array of third-tier isolation trenches having a regular periodicity. The two-dimensional arrays of third-tier isolation trenches may comprise rows of third-tier isolation trenches. Each row of third-tier isolation trenches can be arranged along the first horizontal direction hd1. Each third-tier isolation trench may laterally extend along the first horizontal direction hd1 with a uniform width along the second horizontal direction hd2. The third-tier isolation trenches within each row of third-tier isolation trenches may be laterally spaced from each other along the first horizontal direction hd1 by a spacing that exceeds a lateral dimension of each third-tier isolation opening.

The third-tier isolation openings may be formed as a two-dimensional array of third-tier isolation openings having the same periodicity as the third-tier isolation trenches. The two-dimensional arrays of third-tier isolation openings may comprise rows of third-tier isolation openings. Each row of third-tier isolation openings can be arranged along the first horizontal direction hd1. A two-dimensional array of third-tier isolation openings may be interlaced with the two-dimensional array of third-tier isolation trenches such that a third-tier isolation opening is provided between each neighboring pair of third-tier isolation trenches that are laterally spaced from each other along the first horizontal direction hd1.

The combination of the third-tier isolation trenches and the third-tier isolation openings laterally extends between neighboring clusters of third-tier memory openings. Each laterally alternating sequence of third-tier isolation trenches and the third-tier isolation openings may laterally extend through the third memory array region 100A, the inter-array region 200, and the second memory array region 100B. Laterally alternating sequences of a first type comprise respective third-tier isolation trenches and respective third-tier isolation openings, and extend between neighboring pairs of third retro-stepped dielectric material portions 365. Laterally alternating sequences of a second type comprise respective third-tier isolation trenches and respective third-tier isolation openings, and extend through a respective third retro-stepped dielectric material portion 365. Each repetition unit RU may comprise a third retro-stepped dielectric material portion 365, a laterally alternating sequence of a first type, and a laterally alternating sequence of a second type.

The sacrificial third-tier contact openings can be formed through the third retro-stepped dielectric material portions 365 through a respective horizontally-extending surface segment of the third stepped surfaces.

The third-tier support openings can be formed in the inter-array region 200 in areas that are not filled with the sacrificial third-tier contact openings and the third-tier isolation-region openings (i.e., the third-tier isolation openings and the third-tier isolation trenches).

A sacrificial fill material can be deposited in the various third-tier openings to form various sacrificial third-tier opening fill structures. The various sacrificial third-tier opening fill structures comprise sacrificial third-tier memory opening fill structures 348 that are formed in the third-tier memory openings, sacrificial third-tier support opening fill structures 318 that are formed in the third-tier support openings, sacrificial third-tier contact opening fill structures 368 that are formed in the sacrificial third-tier contact openings, sacrificial third-tier isolation opening fill structures 338 that are formed in the third-tier isolation openings, and sacrificial third-tier wall structures 378 that are formed in the third-tier isolation trenches. The sacrificial fill material in the various sacrificial third-tier opening fill structures comprises a material that is different from the materials of the third insulating layers 332 and the third sacrificial material layers 342. For example, the sacrificial fill material in the various sacrificial third-tier opening fill structures may comprise a semiconductor material (such as amorphous silicon or silicon-germanium).

Each sacrificial third-tier memory opening fill structure 348 may be formed on a top surface of and may have an areal overlap in the plan view with a respective sacrificial second-tier memory opening fill structure 248. Each sacrificial third-tier support opening fill structure 318 may be formed on a top surface of and may have an areal overlap in the plan view with a respective sacrificial second-tier support opening fill structure 218. Each sacrificial third-tier contact opening fill structure 368 may be formed on a top surface of and may have an areal overlap in the plan view with a respective sacrificial second-tier contact opening fill structure 268. Each sacrificial third-tier isolation opening fill structure 338 may be formed on a top surface of and may have an areal overlap in the plan view with a respective sacrificial second-tier isolation opening fill structure 238. Each sacrificial third-tier wall structure 378 may be formed on a top surface of and may have an areal overlap in the plan view with a respective sacrificial second-tier wall structure 278.

In summary, at least one vertically alternating sequence {(132, 142), (232, 242), (332, 342)} of continuous insulating layers (132, 232, 332) and continuous sacrificial material layers (142, 242, 342) can be formed over the semiconductor material layer 110. In one embodiment, the at least one vertically alternating sequence {(132, 142), (232, 242), (332, 342)} comprises a first-tier vertically alternating sequence (132, 142) of first continuous insulating layers 132 and first continuous sacrificial material layers 142 and a second-tier vertically alternating sequence (232, 242) of second continuous insulating layers 232 and second continuous sacrificial material layers 242.

In one embodiment, a first insulating cap layer 170 can be formed between the first-tier vertically alternating sequence (132, 142) and the second-tier vertically alternating sequence (232, 242), and a second insulating cap layer 270 can be formed over the second-tier vertically alternating sequence (232, 242). In one embodiment, the first insulating cap layer 170 and the second insulating cap layer 270 have a same material composition as the first continuous insulating layers 132 and second continuous insulating layers 232.

In one embodiment, each of the first insulating cap layer 170 and the second insulating cap layer 270 comprises a respective two-dimensional array of cylindrical openings and a respective two-dimensional array of rectangular openings upon formation of sets of isolation-region sacrificial fill material portions (138, 238, 338, 178, 278, 378). Each of the isolation opening fill structures (138, 238, 338) may be formed within a respective cylindrical opening, and each of the wall structures (178, 278, 378) may be formed within a respective rectangular opening. The cylindrical openings and rectangular openings do not merge within a same tier structure. Generally, sets of isolation-region sacrificial fill material portions (138, 238, 338, 178, 278, 378) can be formed in the at least one vertically alternating sequence {(132, 142), (232, 242), (332, 342)}. Each set of isolation-region sacrificial fill material portions (138, 238, 338, 178, 278, 378) comprises a laterally alternating sequence of sacrificial wall structures (178, 278, 378) and sacrificial isolation opening fill structures (138, 238, 338) that alternate along a first horizontal direction hd1.

In one embodiment, the first insulating cap layer 170 comprises a two-dimensional array of first cylindrical openings through which the sacrificial first-tier isolation opening fill structures 138 vertically extend; and the second insulating cap layer 270 comprises a two-dimensional array of second cylindrical openings through which the sacrificial second-tier isolation opening fill structures 238 vertically extend. In one embodiment, the first insulating cap layer 170 comprises a two-dimensional array of first rectangular openings through which the sacrificial first-tier wall structures 178 vertically extend; and the second insulating cap layer 270 comprises a two-dimensional array of second cylindrical openings through which the sacrificial second-tier wall structures 278 vertically extend.

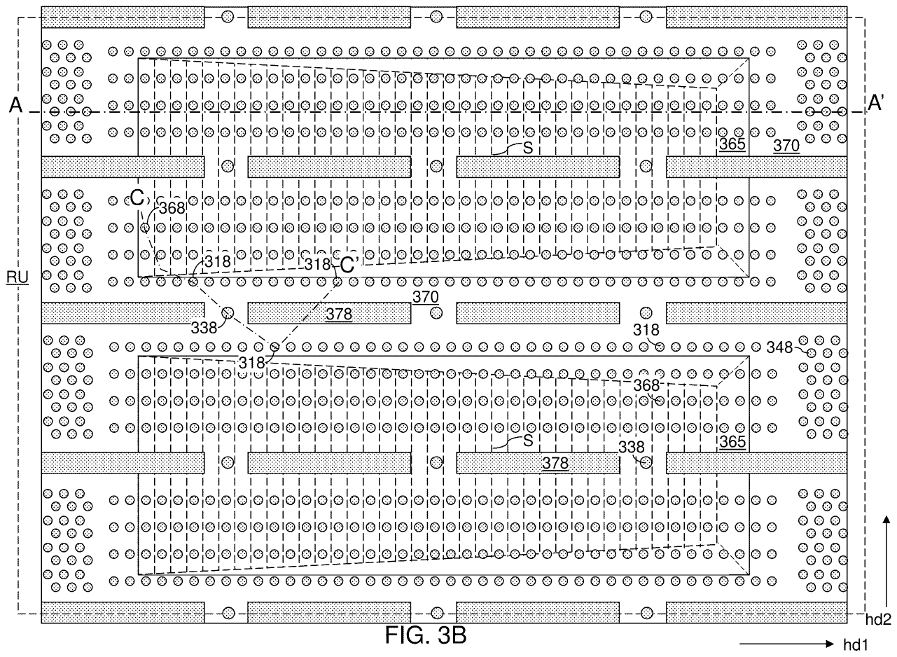

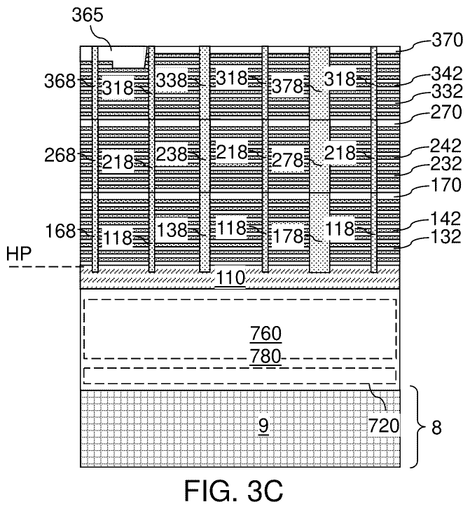

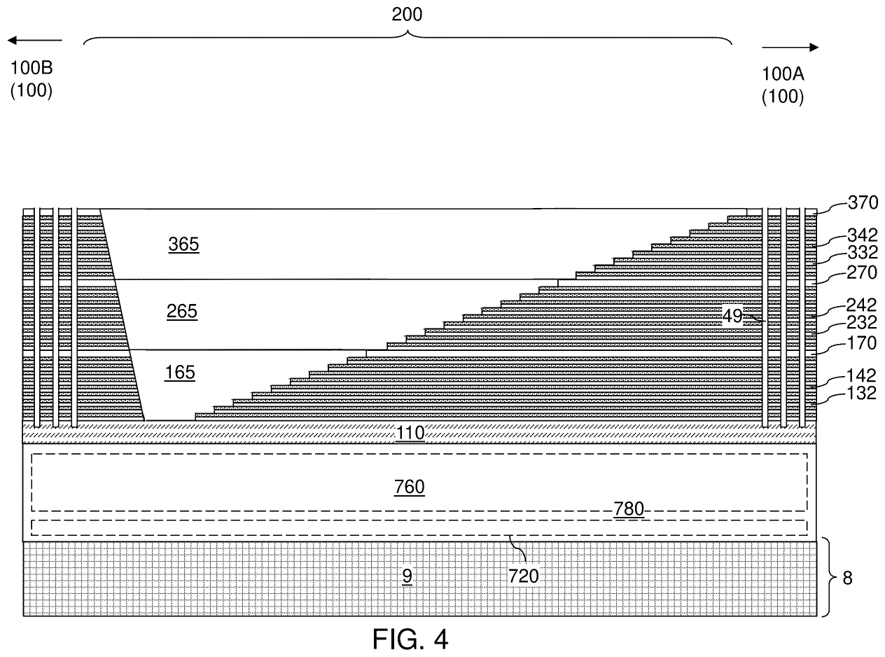

Referring to FIG. 4, a masking layer, such as a photoresist layer (not shown), can be deposited over the structure of FIGS. 3A-3C, and patterned to expose the sacrificial third-tier opening fill structures 348, the sacrificial second-tier opening fill structures 248, and the sacrificial first-tier opening fill structures 148. The exposed sacrificial third-tier opening fill structures 348, the sacrificial second-tier opening fill structures 248, and the sacrificial first-tier opening fill structures 148 are removed selectively to the alternating stacks of insulating layers (132, 232, 332) and sacrificial material layers (142, 242, 342) and selectively to the semiconductor material layer 110. An isotropic etch process or an anisotropic etch process may be performed. Inter-tier memory openings 49 are formed in volumes from which the sacrificial memory opening fill structures (348, 248, 148) are removed. Each of the inter-tier memory openings 49 vertically extends through a respective first alternating stack (132, 142), a respective second alternating stack (232, 242), and a respective third alternating stack (332, 342). The inter-tier memory openings 49 are formed in the memory array regions 100. The inter-tier memory openings 49 may also be referred to as memory openings 49. The photoresist layer may then be removed by ashing or another suitable method.

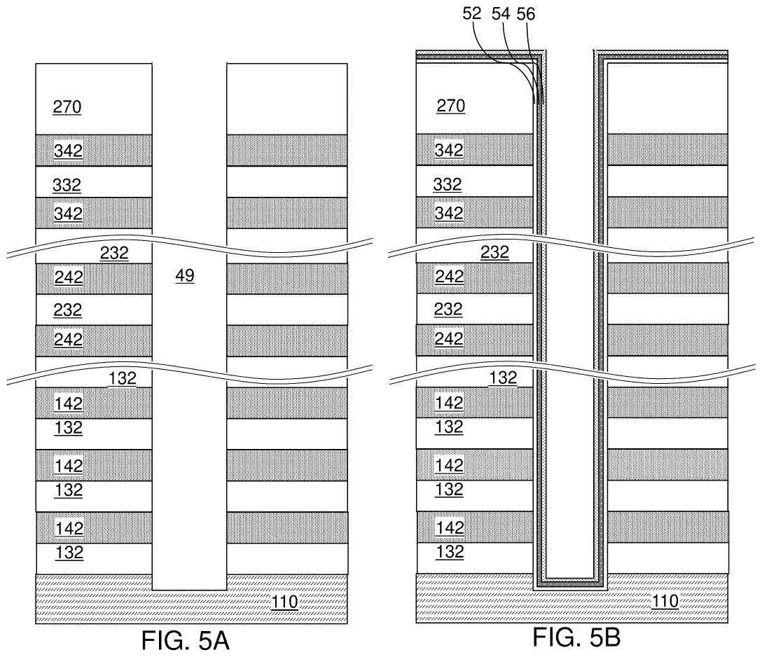

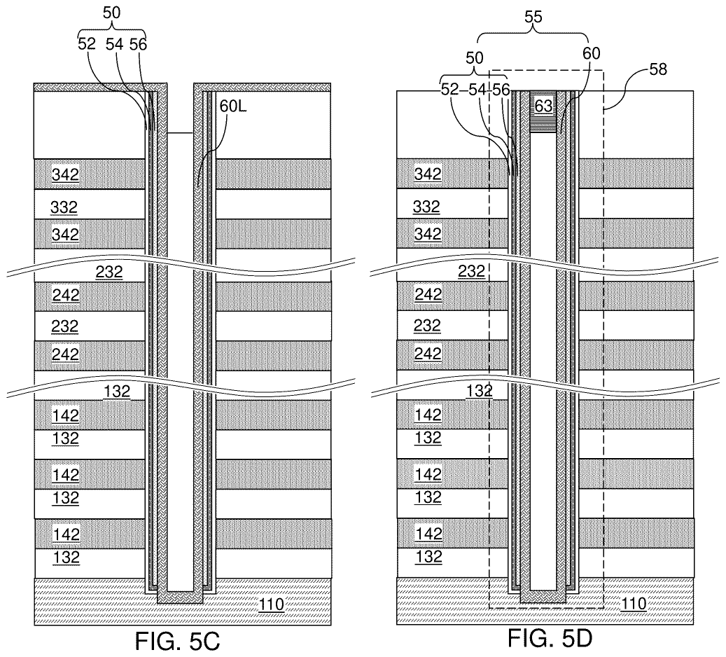

FIGS. 5A-D illustrate sequential vertical cross-sectional views of a memory opening 49 during formation of a memory opening fill structure according to an embodiment of the present disclosure.

Referring to FIG. 5A, a memory opening 49 in the exemplary structure of FIG. 14 is illustrated. The memory opening 49 extends through a first-tier structure, a second-tier structure, and a third-tier structure.

Referring to FIG. 5B, a stack of layers including an optional blocking dielectric layer 52, a memory material layer 54, an optional dielectric liner 56, and a semiconductor channel material layer 60L can be sequentially deposited in the memory openings 49. The blocking dielectric layer 52 can include a single dielectric material layer or a stack of a plurality of dielectric material layers. In one embodiment, the blocking dielectric layer can include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 can include a dielectric metal oxide having a dielectric constant greater than 7.9, i.e., having a dielectric constant greater than the dielectric constant of silicon nitride. The thickness of the dielectric metal oxide layer can be in a range from 1 nm to 20 nm, although lesser and greater thicknesses can also be employed. The dielectric metal oxide layer can subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 can include a dielectric semiconductor compound such as silicon oxide, silicon oxynitride, silicon nitride, or a combination thereof.

Subsequently, the memory material layer 54 can be formed. Generally, the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer.

The optional dielectric liner 56, if present, includes a dielectric material. In case the memory material layer 54 comprises a charge storage material, the dielectric liner 56 comprises a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed. The stack of the blocking dielectric layer 52, the memory material layer 54, and the dielectric liner 56 constitutes a memory film 50 that stores memory bits.

Referring to FIG. 5C, an anisotropic etch process can be performed to remove horizontally-extending portions of the dielectric liner 56, the memory material layer 54, and the blocking dielectric layer 52. Each remaining contiguous combination of an optional blocking dielectric layer 52, a memory material layer 54, and an optional dielectric liner 56 constitutes a memory film 50. A top surface of the semiconductor material layer 110 can be physically exposed at the bottom of each memory opening 49.

A semiconductor channel material layer 60L can be conformally deposited over the memory film 50 within each memory opening 49. The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L includes amorphous silicon or polysilicon. The semiconductor channel material layer 60L can be formed by a conformal deposition method such as low pressure chemical vapor deposition (LPCVD). The thickness of the semiconductor channel material layer 60L can be in a range from 2 nm to 10 nm, although lesser and greater thicknesses can also be employed. A cavity may be present in the volume of each memory opening 49 that is not filled with the deposited material layers (52, 54, 56, 60L).

In case the cavity in each memory opening is not completely filled by the semiconductor channel material layer 60L, a dielectric core layer can be deposited in the cavity to fill any remaining portion of the cavity within each memory opening. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. The horizontal portion of the dielectric core layer overlying the second insulating cap layer 270 can be removed, for example, by a recess etch. The recess etch continues until top surfaces of the remaining portions of the dielectric core layer are recessed to a height between the top surface of the third insulating cap layer 370 and the bottom surface of the third insulating cap layer 370. Each remaining portion of the dielectric core layer constitutes a dielectric core 62.

Referring to FIG. 5D, a doped semiconductor material can be deposited in cavities overlying the dielectric cores 62. The doped semiconductor material has a doping of the opposite conductivity type of the doping of the semiconductor channel material layer 60L. Thus, the doped semiconductor material has a doping of the second conductivity type. Portions of the deposited doped semiconductor material, the semiconductor channel material layer 60L, the dielectric liner 56, the memory material layer 54, and the blocking dielectric layer 52 that overlie the horizontal plane including the top surface of the second insulating cap layer 270 can be removed by a planarization process such as a chemical mechanical planarization (CMP) process.

Each remaining portion of the doped semiconductor material having a doping of the second conductivity type constitutes a drain region 63. The drain regions 63 can have a doping of a second conductivity type that is the opposite of the first conductivity type. For example, if the first conductivity type is p-type, the second conductivity type is n-type, and vice versa. The dopant concentration in the drain regions 63 can be in a range from 5.0×10¹⁸/cm³ to 2.0×10²¹/cm³, although lesser and greater dopant concentrations can also be employed. The doped semiconductor material can be, for example, doped polysilicon.

Each remaining portion of the semiconductor channel material layer 60L constitutes a vertical semiconductor channel 60 through which electrical current can flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of laterally-extending cavities. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a dielectric liner 56, a plurality of memory elements as embodied as portions of the memory material layer 54, and an optional blocking dielectric layer 52. Each combination of a memory stack structure 55, a dielectric core 62, and a drain region 63 within a memory opening 49 constitutes a memory opening fill structure 58.

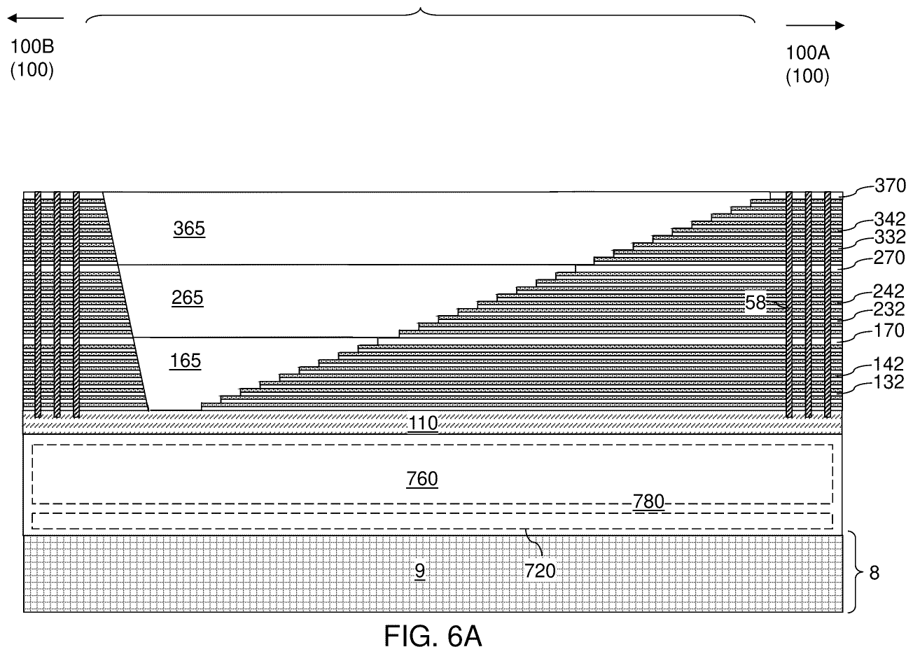

Referring to FIGS. 6A-C, the exemplary structure is illustrated after formation of the memory opening fill structures 58. Support pillar structures (not illustrated) may be formed in support openings, for example, in the inter-array region 200 concurrently with formation of the memory opening fill structures 58. Each of the memory opening fill structures 58 comprises a respective vertical semiconductor channel 60 and respective vertical stack of memory elements, which may comprise portions of the memory material layers 54 located at the levels of the sacrificial material layers (142, 242, 342).

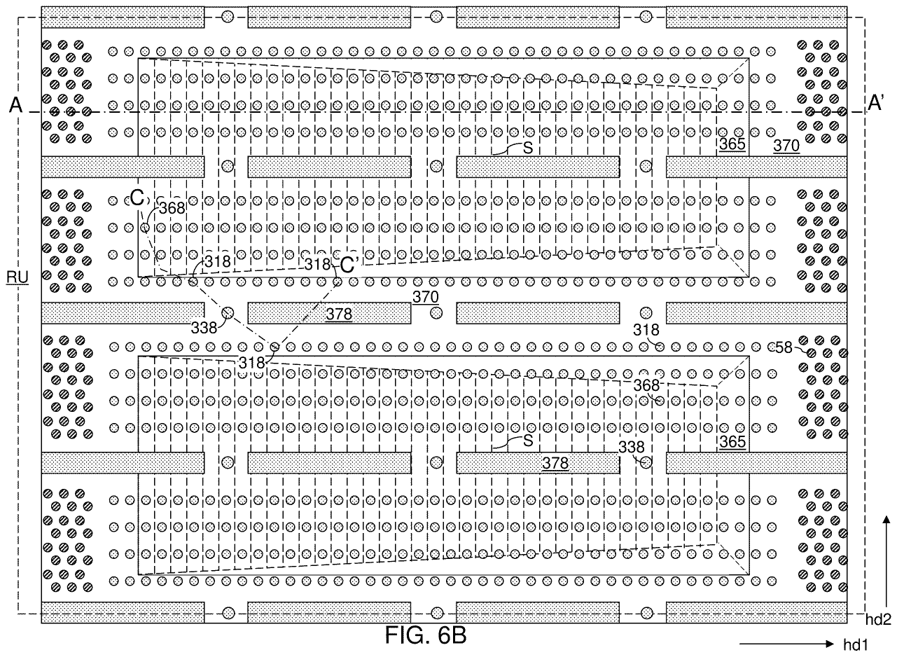

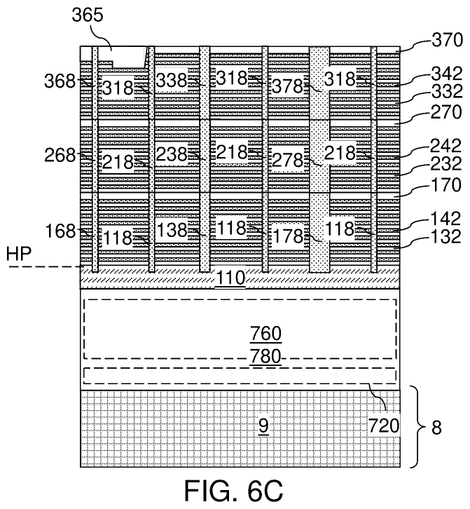

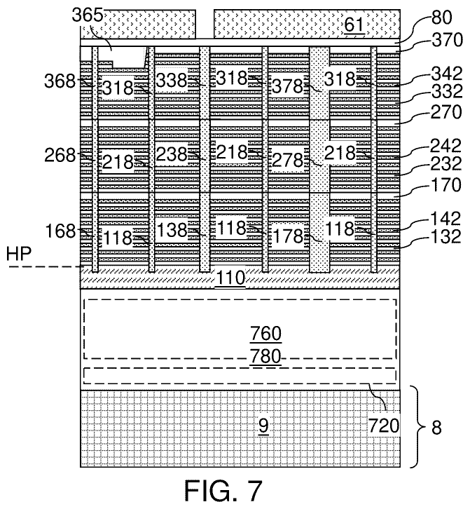

Referring to FIG. 7, a contact-level dielectric layer 80 can be deposited over the third-tier structure. The contact-level dielectric layer 80 comprises a dielectric material that is different from the material of the sacrificial material layers (142, 242, 342). For example, the contact-level dielectric layer 80 comprises silicon oxide. The thickness of the contact-level dielectric layer 80 may be in a range from 100 nm to 800 nm, although lesser or greater thicknesses may also be employed. A patterned photoresist layer 61 can be formed over the contact-level dielectric layer 80. The patterned photoresist layer 61 includes discrete openings over areas of the sacrificial isolation opening fill structures (138, 238, 338).

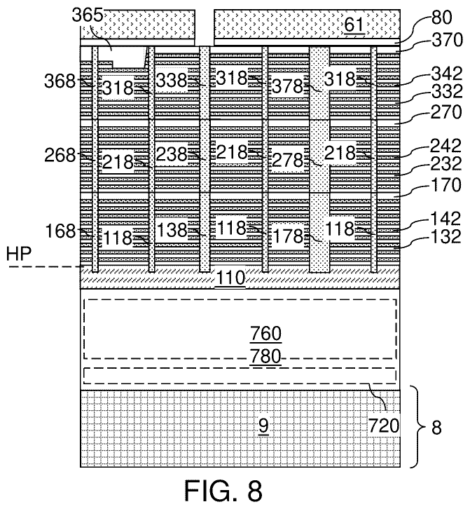

Referring to FIG. 8, an etch process, such as an anisotropic etch process, can be performed to remove unmasked portions of the contact-level dielectric layer 80. Discrete openings are formed through the contact-level dielectric layer 80 over the areas of the sacrificial isolation opening fill structures (138, 238, 338). In one embodiment, the discrete openings may be formed as a two-dimensional periodic array of discrete openings.

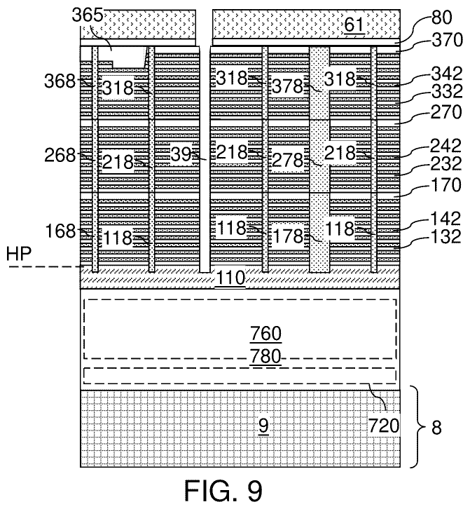

Referring to FIG. 9, a selective etch process can be performed to remove the materials of the sacrificial isolation opening fill structures (138, 238, 338) selectively to the materials of the vertically alternating sequences {(132, 142), (232, 242), (332, 342)}, the insulating cap layers (170, 270, 370), the contact-level dielectric layer 80, and the semiconductor material layer 110. For example, if the sacrificial isolation opening fill structures (138, 238, 338) comprise amorphous silicon, a wet etch process employing tetramethyl ammonium hydroxide (TMAH) or trimethyl-2 hydroxyethyl ammonium hydroxide (TMY) may be performed to remove the sacrificial isolation opening fill structures (138, 238, 338). In this case, an etch stop liner (not illustrated), such as a thin silicon oxide liner, may be formed prior to deposition of the sacrificial fill materials of the sacrificial first-tier fill structures (138, 118, 168, 178, 148) at the processing steps of FIGS. 1A-1C to protect the semiconductor material layer 110 during the wet etch process. Any remaining portion of the patterned photoresist layer 61 may be subsequently removed, for example, by ashing. Inter-tier isolation openings 39, which are also referred to as isolation openings 39, are formed in the volumes from which the sacrificial isolation opening fill structures (138, 238, 338). The isolation openings 39 may be arranged as a periodic two-dimensional array, such as a rectangular array.

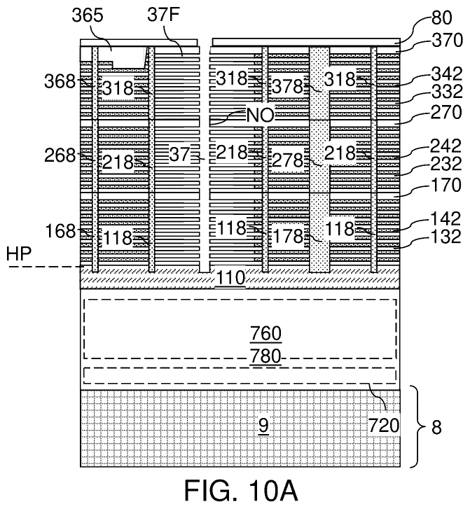

Referring to FIGS. 10A and 10B, a first isotropic etch process can be performed. The first isotropic etch process has an etch chemistry that etches the material of the continuous sacrificial material layers (142, 242, 342) selectively to the material of the continuous insulating layers (132, 232, 332) and the insulating cap layers (170, 270, 370), and selectively to a material of the sacrificial wall structures (178, 278, 378), the sacrificial contact opening fill structures (168, 268, 368), and the sacrificial isolation opening fill structures (138, 238, 338). In an illustrative example, the continuous sacrificial material layers (142, 242, 342) may comprise silicon nitride, and the continuous insulating layers (132, 232, 332) and the insulating cap layers (170, 270, 370) may comprise silicon oxide. In this case, the first isotropic etch process may comprise a wet etch process employing hot phosphoric acid.

The duration of the first isotropic etch process can be selected such that the etch distance of the first isotropic etch process for the material of the continuous sacrificial material layers (142, 242, 342) is greater than the lateral distance between an isolation opening 39 and a respective most proximal sacrificial wall structures (178, 278, 378). In an illustrative example, the etch distance of the first isotropic etch process for the material of the continuous sacrificial material layers (142, 242, 342) may be in a range from 60 nm to 600 nm, such as from 120 nm to 400 nm, although lesser or greater etch distances may also be employed. The etch distance of the first isotropic etch process for the material of the continuous sacrificial material layers (142, 242, 342) may be in a range from 2 times the thickness of each continuous sacrificial material layer (142, 242, 342) to 20 times the thickness of each continuous sacrificial material layer (142, 242, 342).

Thus, each continuous sacrificial material layer (142, 242, 342) that laterally extends over multiple repetition units RU along the second horizontal direction hd2 is divided into a plurality of discrete sacrificial material layers (142, 242, 342). Each such divided portion of a continuous sacrificial material layer (142, 242, 342) is herein referred to as a sacrificial material layer (142, 242, 342). The sacrificial material layers (142, 242, 342) comprise first sacrificial material layers 142 that are divided portions of a respective first continuous sacrificial material layer 142, second sacrificial material layers 242 that are divided portions of a respective second continuous sacrificial material layer 242, and third sacrificial material layers 342 that are divided portions of a respective third continuous sacrificial material layer 342. Each sacrificial material layer (142, 242, 342) may have a lateral extent along the second horizontal direction hd2 that is less than one half of the lateral extent of a repetition unit RU along the second horizontal direction hd2. Annular fin-shaped voids are formed at each level of the sacrificial material layers (142, 242, 342) around each isolation opening 39. Each contiguous volume of an isolation opening 39 and adjoined annular fin-shaped voids 37F constitute a finned isolation opening 37. Each continuous sacrificial material layer (142, 242, 342) can be divided into multiple sacrificial material layers (142, 242, 342) by laterally alternating sequences of finned isolation openings 37 and sacrificial wall structures (178, 278, 378).

Sidewall surface segments of the sacrificial wall structures (178, 278, 378) can be physically exposed to the annular fin-shaped voids 37F of the finned isolation openings 37. Further, a first subset of the sacrificial support opening fill structures (118, 218, 318) may have sidewall surface segments that are exposed to the annular fin-shaped voids 37F of the finned isolation openings 37. In other words, the finned isolation openings 37 may be laterally bounded by sidewall surface segments of the first subset of the sacrificial support opening fill structures (118, 218, 318). A second subset of the sacrificial support opening fill structures (118, 218, 318) are not exposed to any of the finned isolation openings 37. Relatively narrow neck openings NO portions of the finned isolation openings 37 extend through the insulating cap layers (170, 270, 370). The diameter of the neck openings NO correspond to the diameter of the isolation opening 39

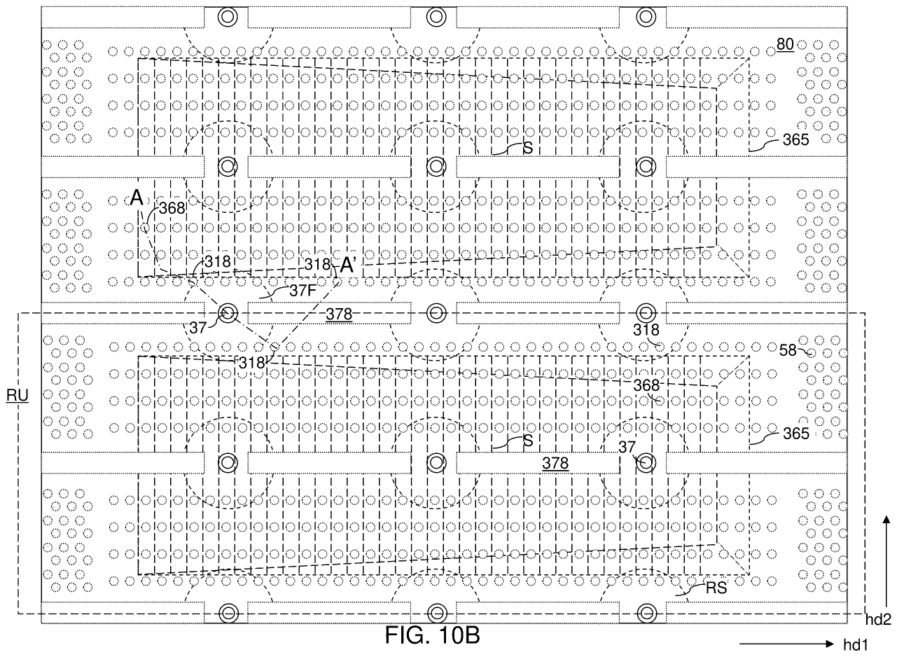

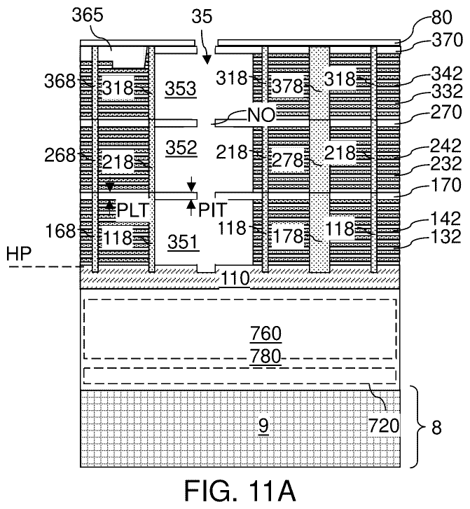

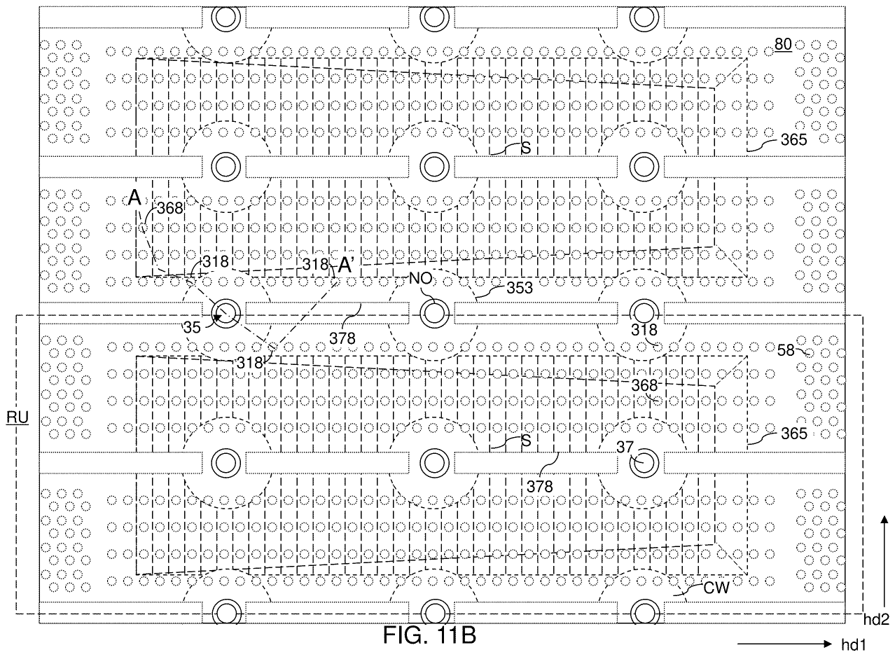

Referring to FIGS. 11A and 11B, a second isotropic etch process can be performed, which etches the material of the continuous insulating layers (132, 232, 332) and the insulating cap layers (170, 270, 370) selectively to the material of the sacrificial wall structures (178, 278, 378). The second isotropic etch process may also etch the material of the continuous insulating layers (132, 232, 332) and the insulating cap layers (170, 270, 370) selectively to the material of the sacrificial material layers (142, 242, 342). In an illustrative example, the continuous insulating layers (132, 232, 332) and the insulating cap layers (170, 270, 370) may comprise silicon oxide, and the second isotropic etch process may comprise a wet etch process employing dilute hydrofluoric acid.

The duration of the second isotropic etch process can be selected such that the etch distance of the second isotropic etch process for the material of the continuous insulating layers (132, 232, 332) and the insulating cap layers (170, 270, 370) is greater than the thickness of each continuous insulating layer (132, 232, 332), and is less than one half of the thickness of each of the insulating cap layers (170, 270, 370). Thus, annular fin-shaped voids 37F of each finned isolation opening 37 merge with each other, and each finned isolation opening 37 is transformed into a laterally expanded isolation opening 35. Portions of the insulating cap layers (170, 270, 370) overlying or underlying the annular fin-shaped voids are thinned, but are not completely removed, by the second isotropic etch process.

Thus, each continuous insulating layer (132, 232, 332) that laterally extends over multiple repetition units RU along the second horizontal direction hd2 is divided into a plurality of discrete insulating layers (132, 232, 332). Each such divided portion of a continuous insulating layer (132, 232, 332) is herein referred to as an insulating layer (132, 232, 332). The insulating layers (132, 232, 332) comprise first insulating layers 132 that are divided portions of a respective first continuous insulating layer 132, second insulating layers 232 that are divided portions of a respective second continuous insulating layer 232, and third insulating layers 332 that are divided portions of a respective third continuous insulating layer 332. Each insulating layer (132, 232, 332) may have a lateral extent along the second horizontal direction hd2 that is less than one half of the lateral extent of a repetition unit RU along the second horizontal direction hd2. Annular fin-shaped voids 37F of each finned isolation opening 37 are expanded during the second isotropic etch process, and merge within each tier level to form the laterally expanded isolation openings 35.

In one embodiment, each insulating cap layer (170, 270, 370) may have a respective planar-region thickness PLT outside the areas of the laterally expanded isolation openings 35, and may have a respective pillar-region thickness PIT within the areas of the laterally expanded isolation openings 35. The planar-region thickness PLT is greater than any vertical thickness of any of the insulating layers 132 and greater than the pillar-region thickness PIT due to the thinning of the pillar-region thickness PIT during the second isotropic etch. In one embodiment, the first insulating cap layer 170 may have a first planar-region thickness PLT over each of the first vertically alternating sequences (132, 142) of first insulating layers 132 and first sacrificial material layers 142, and may have a first pillar-region thickness PIT less than the thickness PLT in the areas having an areal overlap with the laterally expanded isolation openings 35. Likewise, the second insulating cap layer 270 may have a second planar-region thickness PLT over each of the second vertically alternating sequences (232, 242) of second insulating layers 232 and second sacrificial material layers 242, and may have a second pillar-region thickness PIT less than the thickness PLT in the areas having an areal overlap with the laterally expanded isolation openings 35. The third insulating cap layer 370 may have a third planar-region thickness PLT over each of the third vertically alternating sequences (232, 342) of third insulating layers 332 and third sacrificial material layers 342, and may have a third pillar-region thickness PIT less than the thickness PLT in the areas having an areal overlap with the laterally expanded isolation openings 35.

In summary, voids formed by removal of the sacrificial isolation opening fill structures (138, 238, 338) are laterally expanded by isotropically recessing proximal portions of the continuous sacrificial material layers (142, 242, 342) and proximal portions of the continuous insulating layers (132, 232, 332) to form the laterally-expanded isolation openings 35. The combination of the laterally-expanded isolation openings 35 and the sacrificial wall structures (178, 278, 378) divide the at least one vertically alternating sequence {(132, 142), (232, 242), (332, 342)} into alternating stacks {(132, 142), (232, 242), (332, 342)} of insulating layers (132, 232, 332) and sacrificial material layers (142, 242, 342) that are laterally spaced apart from each other along a second horizontal direction hd2.

Sidewall surface segments of the sacrificial wall structures (178, 278, 378) can be physically exposed to the laterally-expanded isolation openings 35. Further, a first subset of the sacrificial support opening fill structures (118, 218, 318) may have sidewall surface segments that are exposed to the laterally-expanded isolation openings 35. In other words, the laterally-expanded isolation openings 35 may be laterally bounded by sidewall surface segments of the first subset of the sacrificial support opening fill structures (118, 218, 318). A second subset of the sacrificial support opening fill structures (118, 218, 318) are not exposed to any of the laterally-expanded isolation openings 35.

The etch distance of the second isotropic etch process is less than one half of the thickness of the first insulating cap layer 170, is less than one half of the thickness of the second insulating cap layer 270, and is less than one half of the thickness of the third insulating cap layer 370. Thus, the lateral dimensions of openings through the first insulating cap layer 170, the second insulating cap layer 270, and the third insulating cap layer 370 increase by no more than twice the etch distance of the second isotropic etch process during the combined processing steps of the first isotropic etch process and the second isotropic etch process. Thus, each of the laterally-expanded isolation openings 35 has a width modulation in a vertical cross-sectional view such that neck openings NO extend through the insulating cap layers (170, 270, 370).

Each laterally-expanded isolation opening 35 may have a respective first-tier cavity portion 351 embedded within the first-tier structure and having first vertically-extending sidewalls, a respective second-tier cavity portion 352 embedded within the second-tier structure and having second vertically-extending sidewalls, and a respective third-tier cavity portion 353 embedded within the third-tier structure and having third vertically-extending sidewalls. The lateral undulation of the first vertically-extending sidewalls, the second vertically-extending sidewalls, and the third vertically-extending sidewalls may be less than one half of the thickness of each sacrificial material layer (142, 242, 342). The first-tier cavity, the second-tier cavity, and the third-tier cavity of each laterally-expanded isolation opening 35 are interconnected by the neck openings NO through the first insulating cap layer 170 and the second insulating cap layer 270.

In an alternative embodiment, instead of forming the laterally-expanded isolation opening 35 after forming the finned isolation opening 37 shown in FIGS. 10A and 10B, a dielectric liner may be deposited at least into the annular fin-shaped voids 37F of the finned isolation opening 37. The dielectric liner may comprise a silicon oxide liner which fills at least the annular fin-shaped voids 37F to reduce the change of vertical bending on the insulating layers (132, 232, 332).

Referring to FIG. 12, a surface oxidation process may be optionally performed to convert surface portions of the sacrificial support opening fill structures (118, 218, 318), the sacrificial wall structures (178, 278, 378), the sacrificial material layers (142, 242, 342), and the semiconductor material layer 110 that are physically exposed to the laterally-expanded isolation openings 35 to an oxide material, such as silicon oxide. In this case, the sacrificial support opening fill structures (118, 218, 318) and the sacrificial wall structures (178, 278, 378) may include a semiconductor material such as silicon, and the sacrificial material layers (142, 242, 342) may include silicon nitride. The surface oxidation process may comprise a thermal oxidation process. The physically exposed surface portions of the sacrificial support opening fill structures (118, 218, 318), the sacrificial wall structures (178, 278, 378), the sacrificial material layers (142, 242, 342), and the semiconductor material layer 110 are converted into semiconductor oxide liners (e.g., silicon oxide liners) (16, 14, 12). The thickness of the semiconductor oxide liners (16, 14, 12) may be in a range from 1 nm to 10 nm, although lesser or greater thicknesses may also be employed. A substantially horizontal semiconductor oxide liner 12 is formed on the exposed upper surface of the semiconductor material layer 110. The semiconductor oxide liners 14 formed on exposed sidewalls of the sacrificial material layers (142, 242, 342) comprise a vertical stack of semiconductor oxide fins. Vertical semiconductor oxide liners 16 are formed on the exposed sidewalls of the sacrificial support opening fill structures (118, 218, 318) and the sacrificial wall structures (178, 278, 378).

In an alternative embodiment, an additional silicon oxide liner may be conformally deposited on the exposed surfaces of the semiconductor oxide liners (16, 14, 12) to increase the structural integrity of the exemplary structure.

Referring to FIG. 13, a photoresist layer (not shown) can be applied over the contact-level dielectric layer 80, and can be lithographically patterned to form openings in areas of the sacrificial support opening fill structures (118, 218, 328). An etch process can be performed to form openings through the contact-level dielectric layer 80 over each of the sacrificial support opening fill structures (118, 218, 328) such that top surfaces of the sacrificial third-tier sacrificial support opening fill structures 328 are physically exposed. The photoresist layer can be subsequently removed, for example, by ashing.

Referring to FIG. 14, the sacrificial support opening fill structures (118, 218, 328) can be removed selectively to the alternating stacks of insulating layers (132, 232, 332) and sacrificial material layers (142, 242, 342), selectively to the semiconductor oxide liners (16, 14, 12), and selectively to the semiconductor material layer 110. An isotropic etch process or an anisotropic etch process may be performed. Inter-tier support openings 19, which are also referred to as support openings 19, are formed in volumes from which the sacrificial support opening fill structures (318, 218, 118) are removed.

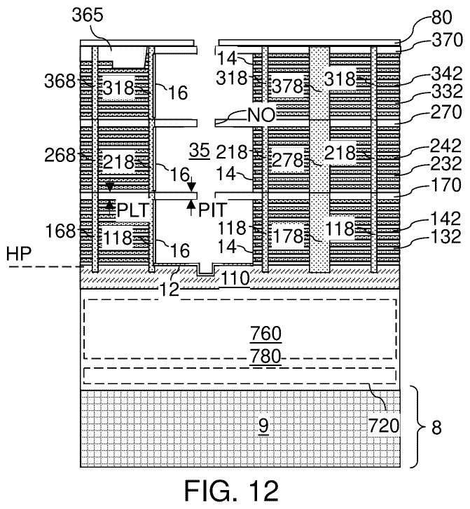

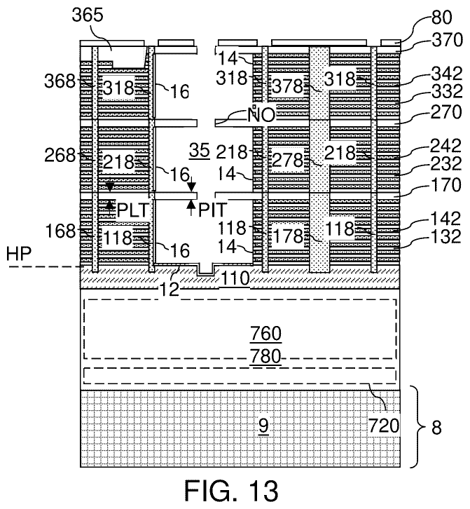

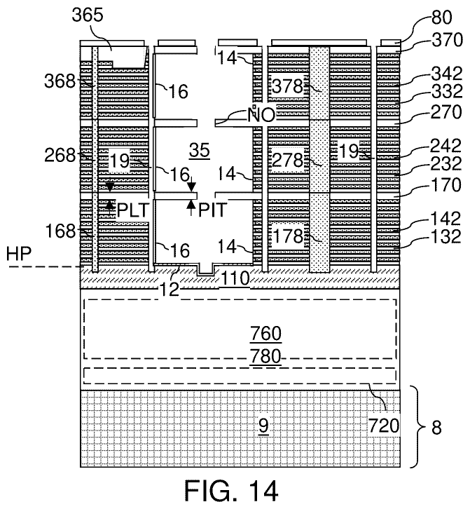

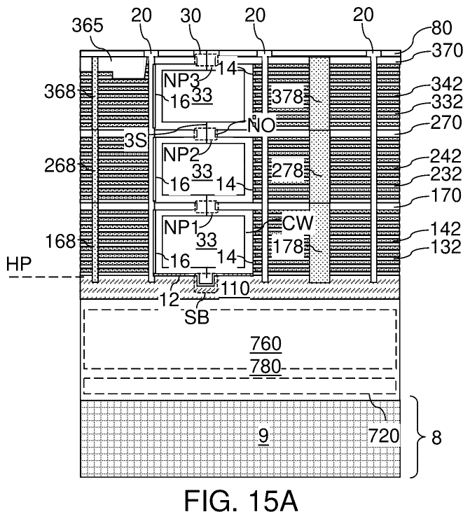

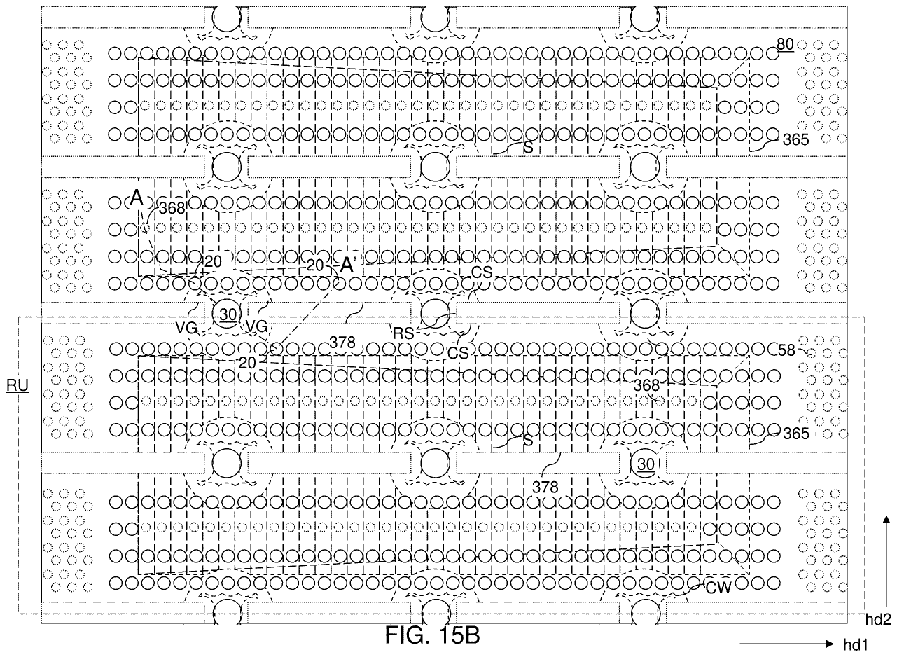

Referring to FIGS. 15A and 15B, a dielectric fill material can be conformally deposited in the laterally-expanded isolation openings 35 and in the support openings 19. The dielectric fill material may comprise undoped silicate glass (i.e., silicon oxide) or a doped silicate glass (such as borosilicate glass, borophosphosilicate glass, a carbon-doped silicate glass, etc.). Optionally, a dielectric metal oxide liner (such as an aluminum oxide liner or a dielectric transition metal oxide liner) may be conformally deposited before deposition of the dielectric fill material. The dielectric fill material is deposited in peripheral regions of the laterally-expanded isolation openings 35 until the neck openings NO are plugged with the deposited dielectric fill material. Encapsulated cavities (i.e., air gaps) 33 that are free of any solid phase material or liquid phase material may be formed within the volume of each laterally-expanded isolation opening 35. The dielectric fill material may fill the support openings 19 without or with vertically-extending seams or encapsulated voids.

Excess portions of the dielectric fill material can be removed from above the horizontal plane including the top surface of the contact-level dielectric layer 80 by performing a planarization process. The planarization process may comprise a recess etch process and/or a chemical mechanical polishing process. Each remaining portion of the dielectric fill material that fills a respective laterally-expanded isolation opening 35 constitutes a cavity-containing dielectric pillar structure 30. Each remaining portion of the dielectric fill material that fills a respective support opening 19 constitutes a dielectric support pillar 20. In one embodiment, top surfaces of the cavity-containing dielectric pillar structures 30 and the dielectric support pillars 20 may be formed within a horizontal plane including the top surface of the contact-level dielectric layer 80.

In summary, a dielectric fill material can be deposited in at least in a peripheral portion of the laterally-expanded isolation openings 35. Cavity-containing dielectric pillar structures 30 can be formed within the laterally-expanded isolation openings 35. Each of the cavity-containing dielectric pillar structures 30 comprises a respective plurality of cylindrical encapsulated cavities (i.e., air gaps) 33 that are vertically stacked and interconnected to each other by at least one vertically-extending seam 3S that is embedded within a respective one of the cavity-containing dielectric pillar structures 30.

The volumes of the cavity-containing dielectric pillar structures 30, the encapsulated cavities 33, and the sacrificial wall structures (178, 278, 378) define lateral isolation trenches that divide neighboring pairs of the at least one vertically alternating sequence of insulating layers (132, 232, 332) and sacrificial material layers (142, 242, 342) (e.g., which divide adjacent memory blocks). Each of the lateral isolation trenches comprises a laterally alternating sequence of uniform width regions (that are filled within the sacrificial wall structures (178, 278, 378)) and laterally-bulging portions (that are filled with the cavity-containing dielectric pillar structures 30) that are interlaced along the first horizontal direction hd1. Each of the uniform width regions is filled with a respective sacrificial wall structure (178, 278, 378) having a uniform width along the second horizontal direction hd2. Each of the laterally-bulging portions is filled with a respective cavity-containing dielectric pillar structure 30 having a greater width along the second horizontal direction hd2 than the sacrificial wall structures (178, 278, 378) and containing at least one encapsulated cavity (i.e., air gap) 33 therein.

In one embodiment shown in FIG. 15B, each of the cavity-containing dielectric pillar structures 30 comprises a pair of vertically-extending grooves VG into which end portions of a pair of sacrificial wall structures (178, 278, 378) fit. In one embodiment, each of the vertically-extending grooves VG comprises a laterally-recessed pillar sidewall RS that is parallel to the second horizontal direction hd2, and a pair of connection sidewalls CS that are adjoined to vertically-extending edges of recessed pillar sidewall RS and are parallel to the first horizontal direction hd1.

In one embodiment, each of the cavity-containing dielectric pillar structure 30 comprises a first bottom surface located within the horizontal plane HP and further comprises a cylindrical downward-protruding stub portion SB that protrudes downward from a periphery of an opening in the first bottom surface into the semiconductor material layer 110.

In one embodiment, the first insulating cap layer 170 comprises a two-dimensional array of first cylindrical openings through which the cavity-containing dielectric pillar structures 30 vertically extend; the second insulating cap layer 270 comprises a two-dimensional array of second cylindrical openings through which the cavity-containing dielectric pillar structures 30 vertically extend; and the third insulating cap layer 370 comprises a two-dimensional array of third cylindrical openings through which the cavity-containing dielectric pillar structures 30 vertically extend. In one embodiment, each of the cavity-containing dielectric pillar structures 30 has a respective first neck portion NP1 at a level of the first insulating cap layer 170, has a respective second neck portion NP2 at a level of the second insulating cap layer 270, and has a respective third neck portion NP3 at a level of the third insulating cap layer 370.

In one embodiment, each of the cavity-containing dielectric pillar structures 30 comprises a first-tier pillar structure that vertically extends through a respective first vertically alternating sequence (132, 142) between the downward-protruding stub portion SB and a first neck portion NP1, a second-tier pillar structure that vertically extends through a respective second vertically alternating sequence (232, 242) between the first neck portion NP1 and a second neck portion NP2, and a third-tier pillar structure that vertically extends through a respective third vertically alternating sequence (332, 342) between the second neck portion NP2 and a third neck portion NP3.

In one embodiment, each cavity-containing dielectric pillar structure 30 comprises a respective plurality of cylindrical encapsulated cavities 33 (i.e., air gaps) that are vertically stacked and interconnected to each other by at least one vertically-extending seam 3S that is embedded within the respective neck portion (NP1, NP2 or NP3) of the respective cavity-containing dielectric pillar structure 30. Each cylindrical encapsulated cavity 33 is laterally bounded by a respective cavity wall CW, which is a vertically-extending surface and having lateral protrusions and lateral recesses in a horizontal cross-sectional view (as illustrated in FIG. 15B). As used herein, a cylindrical shape refers to any shape having a closed periphery in a horizontal cross-sectional view and extending along a vertical direction without any change in the horizontal cross-sectional view. As such, the horizontal cross-sectional view of each cylindrical encapsulated cavity 33 is invariant under translation along the vertical direction.

The dielectric pillar structure 20 may comprise first-type dielectric pillar structures 20 that do not contact any of the cavity-containing dielectric pillar structures 30 and the sacrificial wall structures (178, 278, 378), and second-type dielectric pillar structures 20 in direct contact with the cavity-containing dielectric pillar structures 30. The first-type dielectric pillar structures vertically extend through a respective one of the alternating stacks {(132, 142), (232, 242), (332, 342)}, are laterally spaced from the cavity-containing dielectric pillar structures 30 and the sacrificial wall structures (178, 278, 378), and comprise a respective cylindrical surface segment in direct contact with the respective one of the alternating stacks {(132, 142), (232, 242), (332, 342)} of insulating layers (132, 232, 332) and sacrificial material layers (142, 242, 342). The second-type dielectric pillar structures 20 comprise a respective first cylindrical arc surface segment contacting a respective one the alternating stacks {(132, 142), (232, 242), (332, 342)} and a respective second cylindrical arc surface segment contacting a respective vertical silicon oxide liner 16 that contacts a respective one of the cavity-containing dielectric pillar structures 30.

In one embodiment, each encapsulated cavity 33 within the cavity-containing dielectric pillar structures 30 has a horizontal cross-sectional shape that includes a plurality of concave sidewalls adjacent to the first-type dielectric pillar structures 20, a plurality of convex sidewalls between the first-type dielectric pillar structures 20 and two straight sidewalls extending in the second horizontal direction hd2 adjacent to the sacrificial wall structures (178, 278, 378).

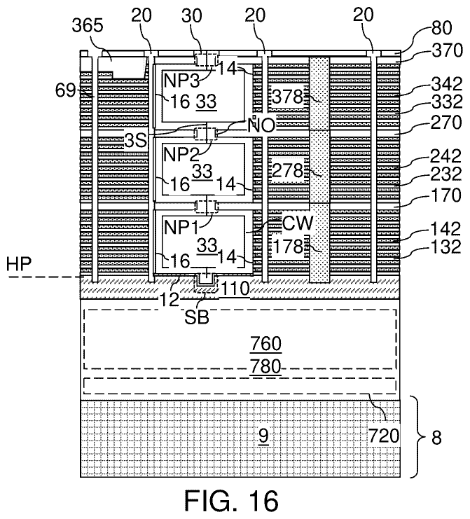

Referring to FIG. 16, a photoresist layer (not shown) can be applied over the contact-level dielectric layer 80, and can be lithographically patterned to form openings over the sacrificial contact openings fill structures (168, 268, 368). An etch process, such as an anisotropic etch process, can be performed to form openings over the sacrificial contact openings fill structures (168, 268, 368). The sacrificial contact opening fill structures (168, 268, 368) are removed selectively to the alternating stacks of insulating layers (132, 232, 332) and sacrificial material layers (142, 242, 342), and selectively to the semiconductor material layer 110. Inter-tier contact openings 69, which are also referred to as contact openings 69, are formed in volumes from which the sacrificial contact opening fill structures (168, 268, 368) are removed. The photoresist layer can be subsequently removed, for example, by ashing.

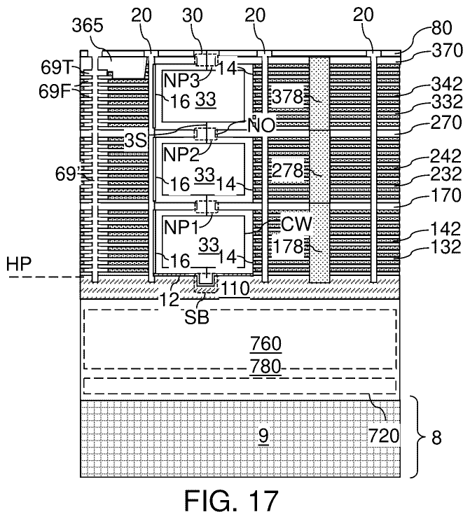

Referring to FIG. 17, a selective isotropic etch process can be performed to isotropically etch portions of the sacrificial material layers (142, 242, 342) that are proximal to the contact openings 69. Fin-shaped voids are formed around each contact opening 69 at each level of the sacrificial material layers (142, 242, 342). Each contiguous combination of a contact opening 69 and adjoined fin-shaped voids constitutes a finned contact opening 69′.

As discussed above, portions of the continuous sacrificial material layers (142, 242, 342) that are exposed to the first stepped cavities, the second stepped cavities, or the third stepped cavities are locally thickened. Thus, for each set of at least one fin-shaped void within a finned contact opening 69′, the topmost fin-shaped void 69T is thicker than the remaining underlying fin-shaped voids 69F.

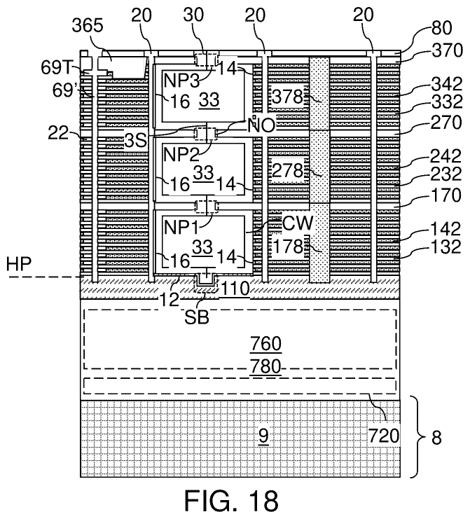

Referring to FIG. 18, a dielectric liner layer can be conformally deposited in peripheral regions of the finned contact openings 69′. The dielectric liner layer comprises a dielectric material having a different material composition than the sacrificial material layers (142, 242, 342). For example, the dielectric liner layer may comprise silicon oxide. The thickness of the dielectric liner layer is greater than one half of the thickness of unthickened portions of the continuous sacrificial material layers (142, 242, 342), and is less than the thickness of locally thickened portions of the continuous sacrificial material layers (142, 242, 342). Thus, for each set of at least one fin-shaped void within a finned contact opening 69′, the topmost fin-shaped void 69T is not completely filled within the dielectric liner layer, while any other fin-shaped void (if present) 69F is completely filled with the dielectric liner layer.

An isotropic recess etch process can be performed to isotropically recess portions of the dielectric liner layer that are deposited outside completely filled fin-shaped voids. Each remaining portion of the dielectric liner layer located in a subset 69F of the fin-shaped voids constitutes an annular insulating spacer 22, while the topmost fin-shaped void 69T remains unfilled. For each finned contact opening 69′ comprising two or more fin-shaped voids, one or more annular insulating spacers 22 are formed in the fin-shaped voids 69F except within the topmost fin-shaped void 69T which has a greater height than the underlying fin-shaped voids 69F (due to the local thickening of the physically exposed portions of the continuous sacrificial material layers (142, 242, 342) discussed above). The annular insulating spacers 22 provide lateral electrical isolation between layer contact via structures to be subsequently formed and electrically conductive layers to be subsequently formed.

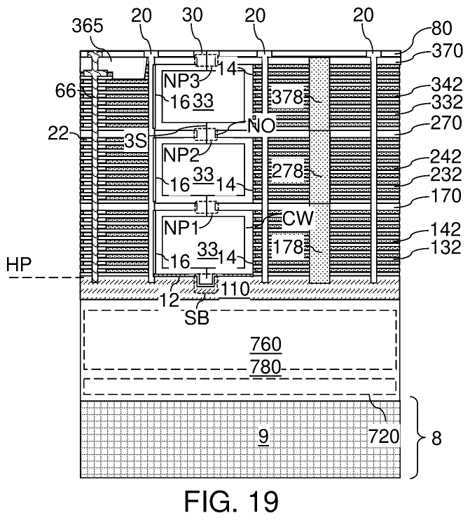

Referring to FIG. 19, a sacrificial via fill material can be deposited in the finned contact openings 69′ including in the topmost fin-shaped void 69T to form sacrificial contact via structures 66. The sacrificial contact via structures 66 may comprise a semiconductor material, such as amorphous silicon.

Referring to FIGS. 20A and 20B, a photoresist layer 67 can be applied over the contact-level dielectric layer 80, and can be lithographically patterned to form openings over the sacrificial wall structures (178, 278, 378). In one embodiment, each opening in the photoresist layer 67 may extend over a respective one of the sacrificial wall structures (178, 278, 378). In one embodiment, a two-dimensional rectangular array of openings may be formed in the photoresist layer 67.

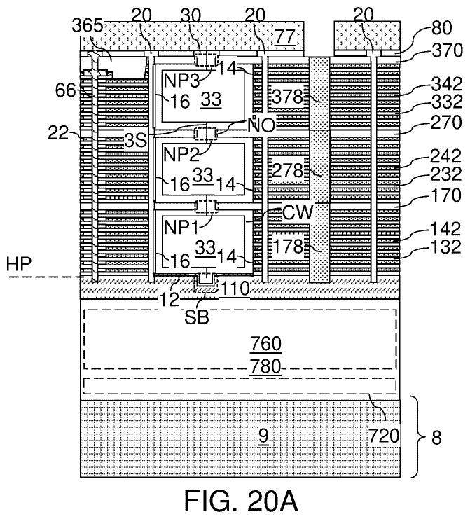

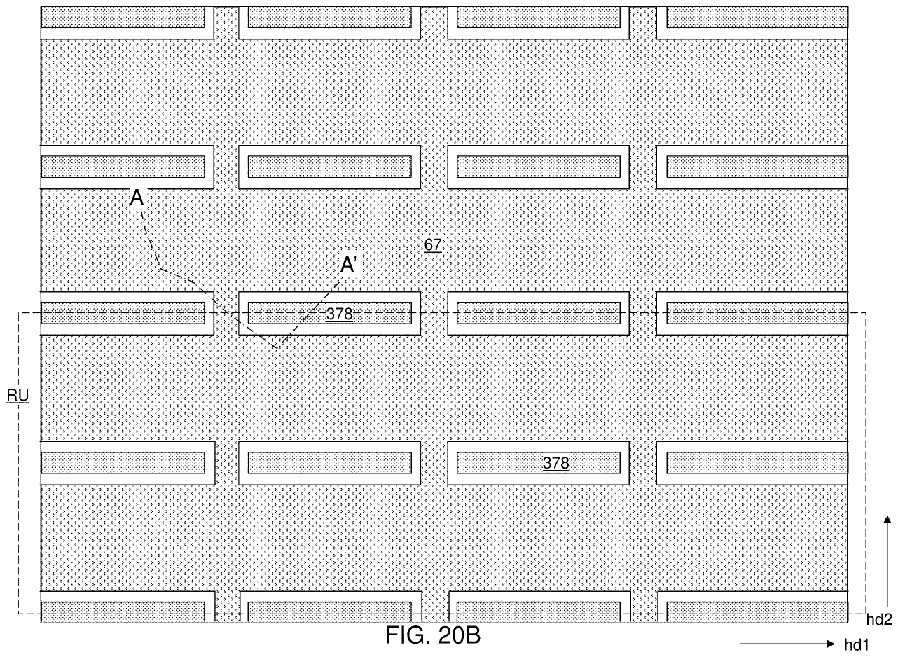

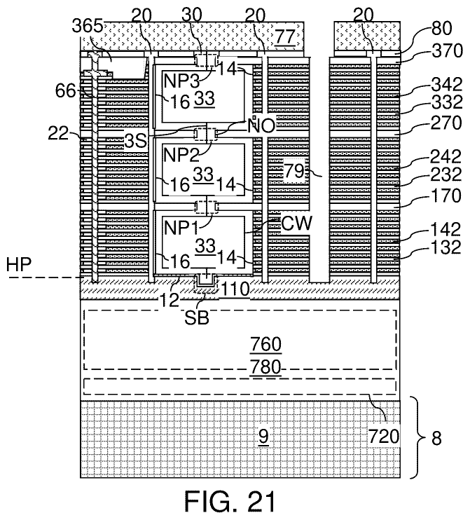

Referring to FIG. 21, the sacrificial wall structures (178, 278, 378) can be removed selectively to the alternating stacks of insulating layers (132, 232, 332) and sacrificial material layers (142, 242, 342). An isotropic etch process or an anisotropic etch process may be performed. Inter-tier lateral isolation trenches 79, which are also referred to as lateral isolation trenches 79, are formed in volumes from which the sacrificial wall structures (178, 278, 378) are removed.

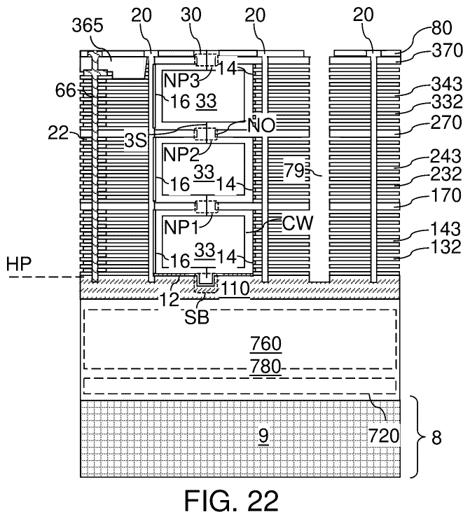

Referring to FIG. 22, an etchant that selectively etches the materials of the sacrificial material layers (142, 242, 342) with respect to the materials of the insulating layers (132, 232, 332), the insulating cap layers (170, 270, 370), the contact-level dielectric layer 80, the retro-stepped dielectric material portions (165, 265, 365), and the material of the outermost layer of the memory films 50 can be introduced into the lateral isolation trenches 79, for example, employing an isotropic etch process. For example, the sacrificial material layers (142, 242, 342) can include silicon nitride, the materials of the insulating layers (132, 232, 332), the insulating cap layers (170, 270, 370), the material of the retro-stepped dielectric material portions (165, 265, 365), and the material of the outermost layer of the memory films 50 can include silicon oxide materials.

The isotropic etch process can be a wet etch process employing a wet etch solution, or can be a gas phase (dry) etch process in which the etchant is introduced in a vapor phase into the lateral isolation trenches 79. For example, if the sacrificial material layers (142, 242, 342) include silicon nitride, the etch process can be a wet etch process in which the exemplary structure is immersed within a wet etch tank including phosphoric acid, which etches silicon nitride selectively to silicon oxide, silicon, and various other materials employed in the art. Laterally-extending cavities (143, 243, 343) are formed in the volumes from which the sacrificial material layers (142, 242, 342) are removed.

Each of the laterally-extending cavities (143, 243, 343) can be a laterally extending cavity having a lateral dimension that is greater than the vertical extent of the cavity. In other words, the lateral dimension of each of the laterally-extending cavities (143, 243, 343) can be greater than the height of the respective laterally-extending cavity (143, 243, 343). A plurality of first laterally-extending cavities 143 can be formed in the volumes from which the material of the first sacrificial material layers 142 is removed. A plurality of second laterally-extending cavities 243 can be formed in the volumes from which the material of the second sacrificial material layers 242 is removed. A plurality of third laterally-extending cavities 343 can be formed in the volumes from which the material of the third sacrificial material layers 342 is removed. Each of the laterally-extending cavities (143, 243, 343) can extend substantially parallel to the top surface of the substrate 8. A laterally-extending cavity (143, 243, 343) can be vertically bounded by a top surface of an underlying insulating layer (132, 232, 332) and a bottom surface of an overlying insulating layer (132, 232, or 332). In one embodiment, each of the laterally-extending cavities (143, 243, 343) can have a uniform height throughout.

Referring to FIG. 23, an outer blocking dielectric layer (not shown) can be optionally deposited in the laterally-extending cavities (143, 243, 343) and the lateral isolation trenches 79 and over the contact-level dielectric layer. At least one conductive material can be deposited in the plurality of laterally-extending cavities (143, 243, 343), on the sidewalls of the lateral isolation trenches 79, and over the contact-level dielectric layer 80. The at least one conductive material can be deposited by a conformal deposition method, which can be, for example, chemical vapor deposition (CVD), atomic layer deposition (ALD), electroless plating, electroplating, or a combination thereof. The at least one conductive material can include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material can include at least one metallic material, i.e., an electrically conductive material that includes at least one metallic element. Non-limiting exemplary metallic materials that can be deposited in the laterally-extending cavities (143, 243, 343) include tungsten, tungsten nitride, titanium, titanium nitride, tantalum, tantalum nitride, cobalt, and ruthenium. For example, the at least one conductive material can include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the laterally-extending cavities (143, 243, 343) can be a combination of titanium nitride layer and a tungsten fill material.

Electrically conductive layers (146, 246, 346) can be formed in the laterally-extending cavities (143, 243, 343) by deposition of the at least one conductive material. A plurality of first electrically conductive layers 146 can be formed in the plurality of first laterally-extending cavities 243, a plurality of second electrically conductive layers 246 can be formed in the plurality of second laterally-extending cavities 243, a plurality of third electrically conductive layers 346 can be formed in the plurality of third laterally-extending cavities 343, and a continuous metallic material layer (not shown) can be formed on the sidewalls of each lateral isolation trench 79 and over the contact-level dielectric layer 80. Each of the electrically conductive layers (146, 246, 346) may include a respective conductive metallic nitride liner and a respective conductive fill material. Thus, the sacrificial material layers (142, 242, 342) can be replaced with the electrically conductive layers (146, 246, 346), respectively. Specifically, each first sacrificial material layer 142 can be replaced with an optional portion of the outer blocking dielectric layer and a first electrically conductive layer 146, each second sacrificial material layer 242 can be replaced with an optional portion of the outer blocking dielectric layer and a second electrically conductive layer 246, and each third sacrificial material layer 342 can be replaced with an optional portion of the outer blocking dielectric layer and a third electrically conductive layer 346. A backside cavity is present in the portion of each lateral isolation trench 79 that is not filled with the continuous metallic material layer.

Residual conductive material can be removed from inside the lateral isolation trenches 79. Specifically, the deposited metallic material of the continuous metallic material layer can be etched back from the sidewalls of each lateral isolation trench 79 and from above the contact-level dielectric layer 80, for example, by an isotropic etchback process. Each remaining portion of the deposited metallic material in the first laterally-extending cavities 143 constitutes a first electrically conductive layer 146. Each remaining portion of the deposited metallic material in the second laterally-extending cavities 243 constitutes a second electrically conductive layer 246. Each remaining portion of the deposited metallic material in the third laterally-extending cavities 343 constitutes a third electrically conductive layer 346. Thus, the sacrificial material layers (142, 242, 342) are replaced with the electrically conductive layers (146, 246, 346).

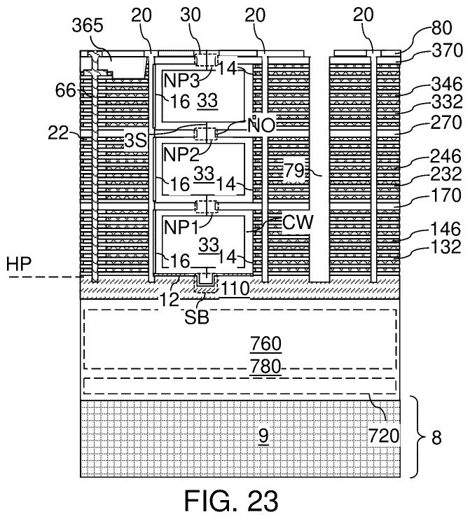

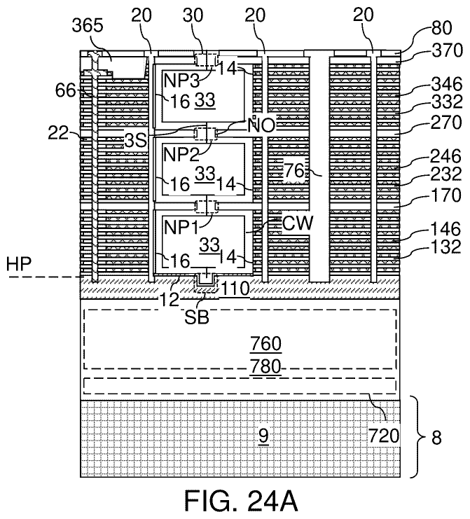

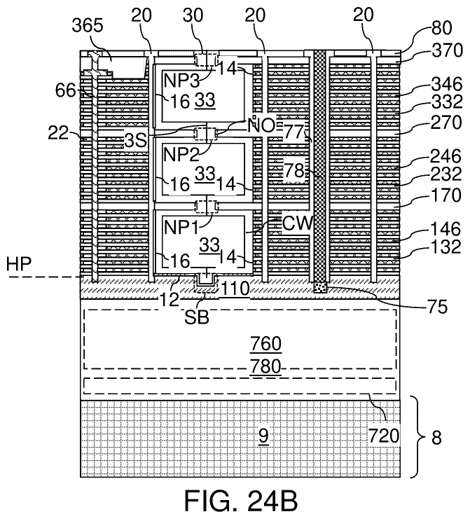

Referring to FIG. 24A, a dielectric fill material such as undoped silicate glass or a doped silicate glass may be deposited in the lateral isolation trenches 79. The dielectric fill material may be deposited by a conformal deposition process (such as a chemical vapor deposition process) or a self-planarizing deposition process (such as spin-coating). Any excess portion of the dielectric fill material overlying the top surface of the contact-level dielectric layer 80 may be removed from above the top surface of the contact-level dielectric layer 80 by a planarization process (which may comprise a recess etch process or a chemical mechanical polishing process). Remaining portions of the dielectric fill material filling the lateral isolation trenches 79 constitute lateral isolation trench fill structures {76, (77, 78)}. In this embodiment, the lateral isolation trench fill structures comprise lateral isolation wall structures 76. Alternatively, the excess portion of the dielectric fill material overlying the top surface of the contact-level dielectric layer 80 may be incorporated into the contact-level dielectric layer 80. Generally, top surfaces of the dielectric isolation wall structures 76 may be formed within the horizontal plane including the top surface of the contact-level dielectric layer 80.

Referring to FIG. 24B, in an alternative embodiment, the dielectric fill material may be conformally deposited only on the sidewalls of the lateral isolation trenches 79. The dielectric fill material is then anisotropically etched using a sidewall spacer etch process to form dielectric sidewall spacers 77. A dopant of a second conductivity type is implanted into the exposed upper portions of the semiconductor material layer 110 through the lateral isolation trenches 79 to form a source region 75. An electrically conductive material is then deposited in the remaining volume of the lateral isolation trenches 79 on the dielectric sidewall spacers to form a source local interconnect 78 in contact with the source region 75. In this embodiment, the lateral isolation trench fill structures {76, (77, 78)} each comprise a combination of the dielectric spacer 77 and the source local interconnect 78.

The exemplary structure comprises alternating stacks {(132, 146), (232, 246), (332, 346)} of insulating layers (132, 232, 332) and electrically conductive layers (146, 246, 346). Each of the alternating stacks {(132, 146), (232, 246), (332, 346)} laterally extends along a first horizontal (i.e., word line) direction hd1. The alternating stacks {(132, 146), (232, 246), (332, 346)} are laterally spaced apart from each other along a second horizontal (e.g., bit line) direction hd2 by lateral isolation trenches that laterally extend along the first horizontal direction hd1. Memory openings 49 vertically extend through a respective one of the alternating stacks {(132, 146), (232, 246), (332, 346)}, and memory opening fill structures 58 are located in a respective one of the memory openings 49 and comprise a vertical semiconductor channel 60 and a respective vertical stack of memory elements (e.g., portions of the memory film 50) located at levels of the electrically conductive layers (146, 246, 346). Each of the lateral isolation trenches 79 comprises a laterally alternating sequence of uniform width regions and laterally-bulging portions that are interlaced along the first horizontal direction hd1. Each of the laterally-bulging portions is filled with a respective cavity-containing dielectric pillar structure 30 containing at least one encapsulated cavity 33 comprising an air gap therein.

In one embodiment, each of the uniform width regions is filled with a respective lateral isolation trench fill structures {76, (77, 78)} having a uniform width along the second horizontal direction hd2. The lateral isolation trench fill structure comprises a lateral isolation wall structure 76 or a combination of a dielectric spacer 77 and a source local interconnect 78. The cavity-containing dielectric pillar structures 30 have a greater width along the second horizontal direction hd2 than the lateral isolation trench fill structure{76, (77, 78)}.

In one embodiment, each of the cavity-containing dielectric pillar structures 30 comprises a pair of vertically-extending grooves VG into which end portions of a pair of lateral isolation trench fill structures {76, (77, 78)} fit. In one embodiment, each of the vertically-extending grooves VG comprises: a laterally-recessed pillar sidewall RS that is parallel to the second horizontal direction hd2; and a pair of connection sidewalls CS that are adjoined to vertically-extending edges of recessed pillar sidewall RS and are parallel to the first horizontal direction hd1.

In one embodiment, the alternating stacks {(132, 146), (232, 246), (332, 346)} are located on a top surface of a semiconductor material layer 110; bottom edges of the laterally-recessed pillar sidewall RS of the vertically-extending grooves VG are located within a horizontal plane HP including the top surface of the semiconductor material layer 110; and bottom edges of the connection sidewalls CS of the vertically-extending grooves VG are located within the horizontal plane HP. In one embodiment, bottom surfaces of the uniform width regions are located below the horizontal plane HP; and bottom surfaces of the laterally-bulging portions are located below the horizontal plane HP. In one embodiment, each of the cavity-containing dielectric pillar structures 30 comprises a first bottom surface located within the horizontal plane HP and further comprises a cylindrical downward-protruding stub portion SB that protrudes downward from a periphery of an opening in the first bottom surface into the semiconductor material layer 110.

In one embodiment, each of the alternating stacks {(132, 146), (232, 246), (332, 346)} comprises, from bottom to top: a first vertically alternating sequence (132, 146) of first-tier insulating layers 132 and first-tier electrically conductive layers 146; and a second vertically alternating sequence (232, 246) of second-tier insulating layers 232 and second-tier electrically conductive layers 246 that overlie the first vertically alternating sequence. In one embodiment, a first insulating cap layer 170 that is thicker than any of the first-tier insulating layers 132 and the second-tier insulating layers 232 continuously extends over multiple first vertically alternating sequences (132, 146) of multiple alternating stacks {(132, 146), (232, 246), (332, 346)}, and below multiple second vertically alternating sequences (232, 246) of the multiple alternating stacks {(132, 146), (232, 246), (332, 346)}; and a second insulating cap layer 270 that is thicker than any of the first-tier insulating layers 132 and the second-tier insulating layers 232 continuously extends over the multiple second vertically alternating sequences (232, 246) of the multiple alternating stacks {(132, 146), (232, 246), (332, 346)}. Portions of the first and the second insulating cap layers which extend through the lateral isolation trenches 79 comprise at least portions of trench bridges TB.

In one embodiment, the first insulating cap layer 170 comprises a two-dimensional array of first cylindrical openings through which the cavity-containing dielectric pillar structures 30 vertically extend; and the second insulating cap layer 270 comprises a two-dimensional array of second cylindrical openings through which the cavity-containing dielectric pillar structures 30 vertically extend. In one embodiment, the first insulating cap layer 170 comprises a two-dimensional array of first rectangular openings through which the lateral isolation wall structures 76 or a combination of the dielectric spacer 77 and source local interconnect 78 vertically extend; and the second insulating cap layer 270 comprises a two-dimensional array of second cylindrical openings through which the lateral isolation wall structures 76 or the combination of the dielectric spacer 77 and source local interconnect 78 vertically extend.

In one embodiment, each of the cavity-containing dielectric pillar structures 30 has a respective first neck portion NP1 at a level of the first insulating cap layer 170, and has a respective second neck portion NP2 at a level of the second insulating cap layer 270; and each of the cavity-containing dielectric pillar structures 30 comprises a first-tier pillar structure that vertically extends through a respective first vertically alternating sequence (132, 146) and a second-tier pillar structure that vertically extends through a respective second vertically alternating sequence (232, 246). In one embodiment, the respective first neck portion NP1 and the respective second neck portion NP2 are laterally spaced from a pair of most proximal lateral isolation wall structures 76 or the combination of the dielectric spacer 77 and source local interconnect 78 by a respective lateral spacing.

In one embodiment, the first insulating cap layer 170 has a first planar-region thickness PLT over each of the first vertically alternating sequences {(132, 146), (232, 246), (332, 346)} and has a first pillar-region thickness PIT over each of the first-tier pillar structures; and the first planar-region thickness PLT is greater than any vertical thickness of any of the first-tier insulating layers 132 and greater than the first pillar-region thickness PIT.

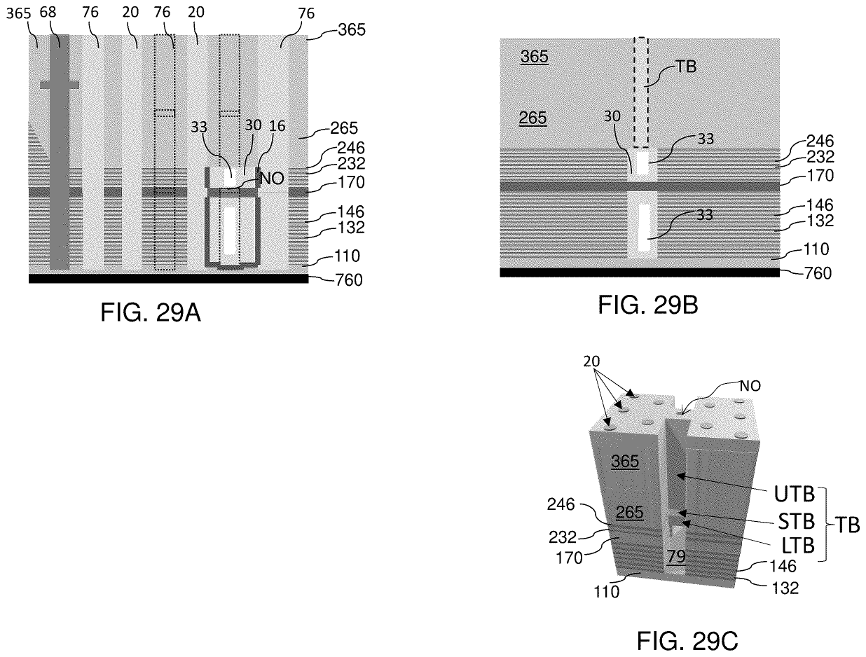

In one embodiment shown in FIG. 29C, the alternating stack further comprises stepped surfaces (i.e., a staircase region in the inter-array region 200); at least one retro-stepped dielectric material portion (165, 265, 365) is located over the stepped surfaces; an upper part UTB of at least one of the trench bridges TB comprises a part of the at least one retro-stepped dielectric material portion which extends through one of the lateral isolation trenches 79; and a lower part LTB of the at least one of the trench bridges TB comprises a portion of the first insulating cap layer 170 which extends through the one of the lateral isolation trenches 79.

In one embodiment, the respective cavity-containing dielectric pillar structure 30 comprises a respective plurality of cylindrical encapsulated cavities (e.g., air gaps) 33 that are vertically stacked and interconnected to each other by at least one vertically-extending seam 3S that is embedded within the respective cavity-containing dielectric pillar structure 30.

In one embodiment, the semiconductor structure also comprises: first-type dielectric pillar structures 20 vertically extending through a respective one of the alternating stacks {(132, 146), (232, 246), (332, 346)}, laterally spaced from the cavity-containing dielectric pillar structures 30 and the lateral isolation wall structures 76 or the combination of the dielectric spacer 77 and source local interconnect 78, and comprising a respective cylindrical surface segment in direct contact with the respective one of the alternating stacks {(132, 146), (232, 246), (332, 346)}; and second-type dielectric pillar structures 20 comprising a respective first cylindrical arc surface segment contacting a respective one the alternating stacks {(132, 146), (232, 246), (332, 346)} and a respective second cylindrical arc surface segment contacting a respective silicon oxide liner that contacts a respective one of the cavity-containing dielectric pillar structures 30.

In one embodiment, each encapsulated cavity 33 within the cavity-containing dielectric pillar structures 30 has a horizontal cross-sectional shape that includes a plurality of concave sidewalls adjacent to the first-type dielectric pillar structures 20, a plurality of convex sidewalls between the first-type dielectric pillar structures 20 and two straight sidewalls extending in the second horizontal direction hd2 adjacent to the lateral isolation wall structures 76 or the combination of the dielectric spacer 77 and source local interconnect 78.

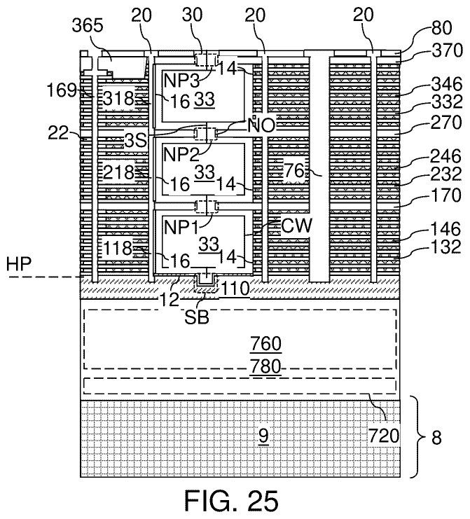

Referring to FIG. 25, the sacrificial contact via structures 66 can be removed by performing a selective isotropic etch process. The selective isotropic etch process has an etch chemistry that etches the material of the sacrificial contact via structures 66 selectively to the materials of the insulating layers (132, 232, 332), the electrically conductive layers (146, 246, 346), the annular insulating spacers 22, and the retro-stepped dielectric material portions (165, 265, 365). Layer contact via cavities 169 are formed in the voids in which the sacrificial contact via structures 66 are removed.

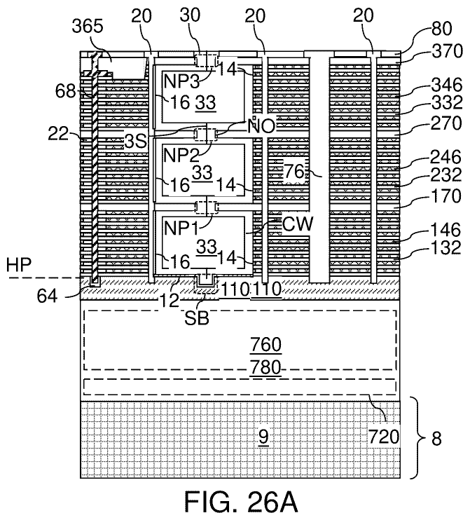

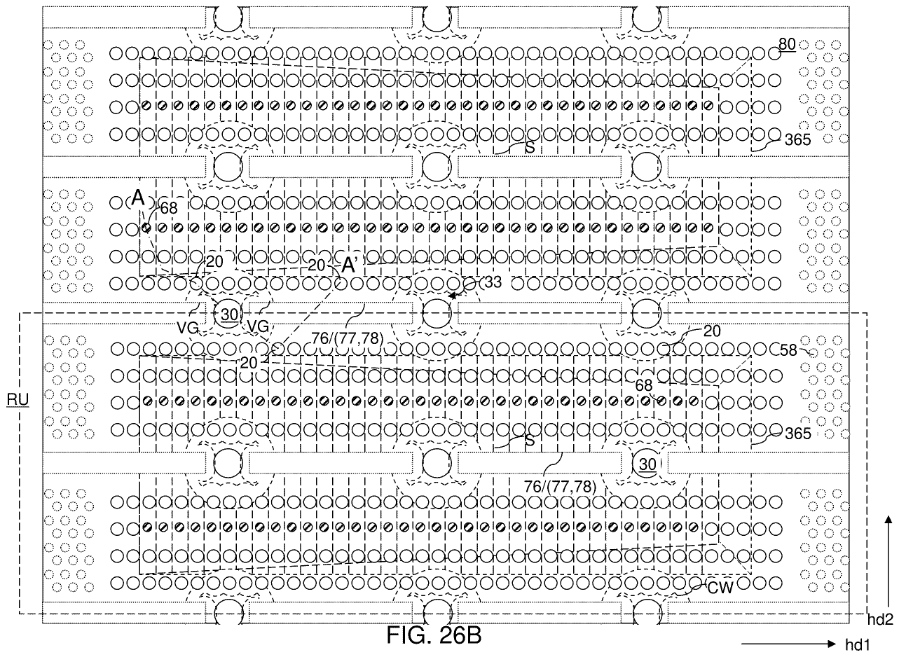

Referring to FIGS. 26A and 26B, isolation spacers 64 may be formed at the bottom of each layer contact via cavity 169, for example, by performing a surface oxidation process that converts physically exposed surface portions of the semiconductor material layer 110 into dielectric semiconductor liners such as silicon oxide liners.

At least one conductive material can be deposited in the layer contact via cavities 169. Excess portions of the at least one conductive material can be removed from above the horizontal plane including the top surface of the contact-level dielectric layer 80 by performing a planarization process such as a chemical mechanical polishing process. Each remaining portion of the at least one conductive material filling a respective layer contact via cavity 169 constitutes a layer contact via structure 68 that contacts a cylindrical sidewall of a respective one of the electrically conductive layers (146, 246, 346). Specifically, the layer contact via structure 68 contacts the cylindrical sidewall of a thickened portion of the respective one of the electrically conductive layers (146, 246, 346) located in the respective topmost fin-shaped void 69T.

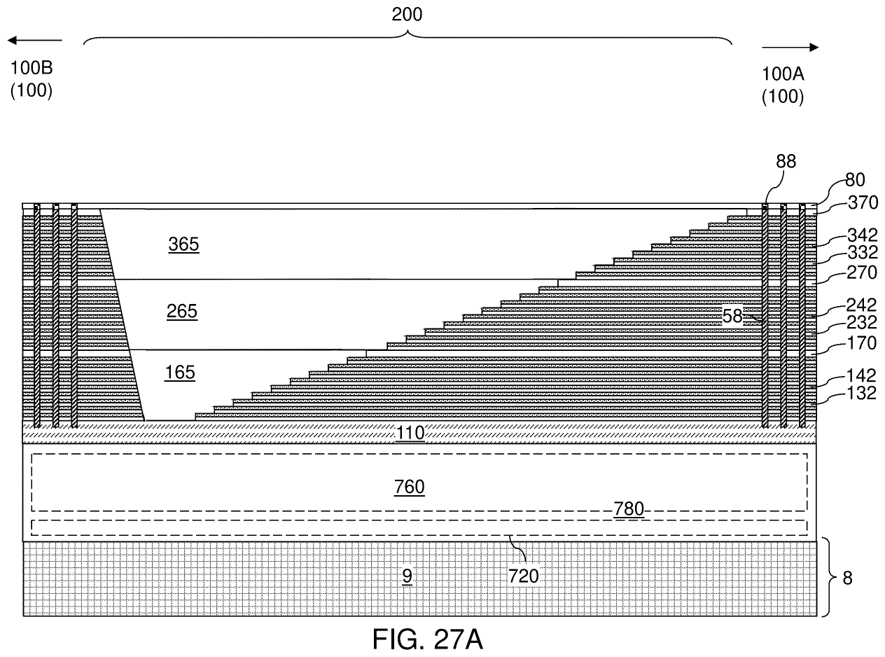

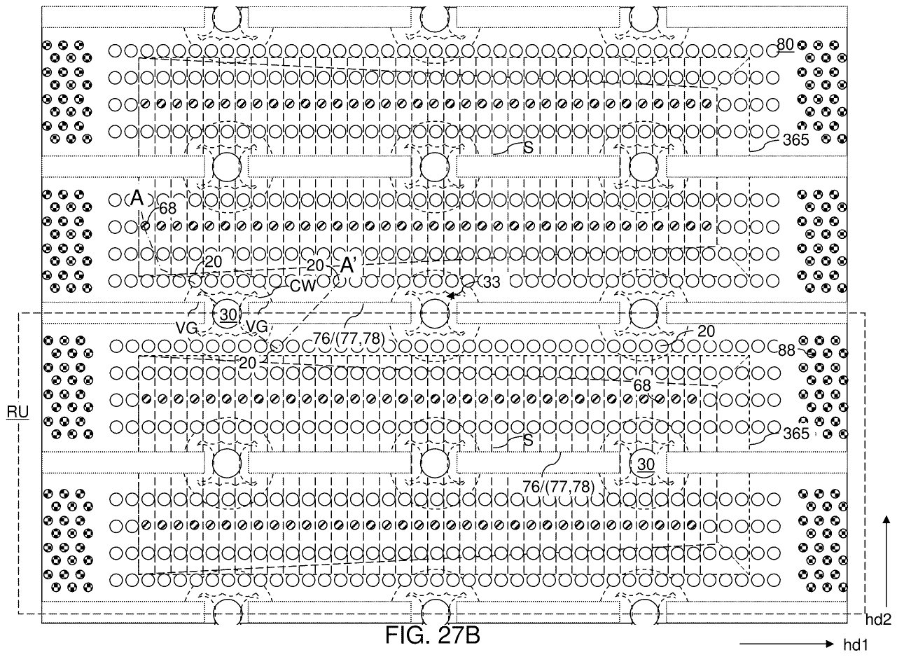

Referring to FIGS. 27A and 27B, drain contact via structures 88 can be formed through the contact-level dielectric layer 80 on top surfaces of the drain regions 63. Subsequently, additional metal interconnect structures (not illustrated) embedded in dielectric material layers can be formed above the contact-level dielectric layer 80. The additional metal interconnect structures include bit lines and other interconnects.

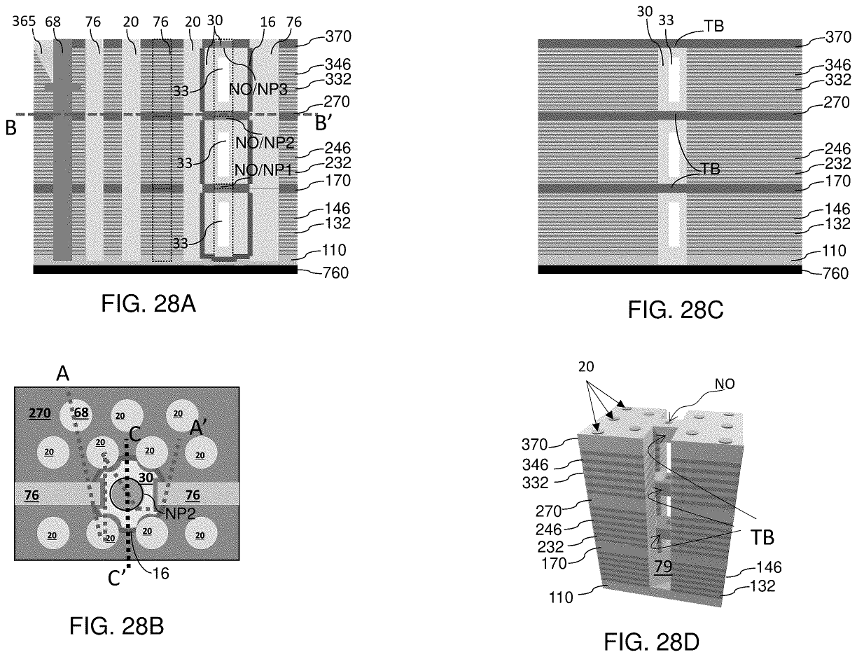

Referring to FIGS. 28A-28D the insulating cap layers (170, 270, 370) comprise inter-tier dielectric layers which include portions which function as trench bridges, TB, after formation of the lateral isolation trenches 79. In other words, the insulating cap layers (170, 270, 370) extend across the lateral isolation trenches 79 to form the trench bridges TB, and the trench bridges TB comprise portions of the insulating cap layers (170, 270, 370) which extend across the lateral isolation trenches 79. The trench bridges TB prevent or reduce the likelihood of the alternating stacks tilting or collapsing into the lateral isolation trenches 79. The trench bridges TB include the neck openings NO which are filled with the respective neck portions (NP1, NP2, NP3) of the cavity-containing dielectric pillar structure 30 at the vertical levels of the respective insulating cap layers (170, 270, 370).

Referring to FIGS. 29A-29C, parts of the retro-stepped dielectric material portions (165, 265, 365) also function as at least portions of the trench bridges TB. Thus, in the lower staircase region of the inter-array region, at least the upper portion of the trench bridge TB comprises a part of at least one retro-stepped dielectric material portion. For example, as shown in FIG. 29C, the upper portion UTB of the trench bridge TB comprises parts of the second and third retro-stepped dielectric material portions (265, 365) which extend across the lateral isolation trench 79, while the lower portion LTB of the trench bridge TB comprises a part of the first insulating cap layer 170 which extends across the lateral isolation trench 79. The upper portion UTB of the trench bridge TB may have a smaller width along the first horizontal direction (e.g., word line direction) hd1 than the lower portion LTB of the trench bridge TB, such that the top surface of the lower portion LTB forms a horizontal step STB along the first horizontal direction hd1.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A semiconductor structure, comprising:
alternating stacks of insulating layers and electrically conductive layers, wherein each of the alternating stacks laterally extends along a first horizontal direction, wherein the alternating stacks are laterally spaced apart from each other along a second horizontal direction by lateral isolation trenches that laterally extend along the first horizontal direction;
memory openings vertically extending through a respective one of the alternating stacks; and
memory opening fill structures located in a respective one of the memory openings and comprising a vertical semiconductor channel and respective vertical stack of memory elements located at levels of the electrically conductive layers,
wherein:
each of the lateral isolation trenches comprises a laterally alternating sequence of uniform width regions and laterally-bulging portions that are interlaced along the first horizontal direction; and
each of the laterally-bulging portions is filled with a respective cavity-containing dielectric pillar structure containing at least one encapsulated cavity comprising an air gap therein.

2. The semiconductor structure of claim 1, wherein:
each of the uniform width regions is filled with a respective lateral isolation trench fill structure;
the lateral isolation trench fill structure comprises a lateral isolation wall structure or a combination of a dielectric spacer and a source local interconnect;
the lateral isolation trench fill structure has a uniform width along the second horizontal direction; and
the cavity-containing dielectric pillar structures have a greater width along the second horizontal direction than the lateral isolation trench fill structure.

3. The semiconductor structure of claim 2, wherein:
each of the cavity-containing dielectric pillar structures comprises a pair of vertically-extending grooves into which end portions of a pair of the lateral isolation trench fill structures fit; and
each of the vertically-extending grooves comprises:
a laterally-recessed pillar sidewall that is parallel to the second horizontal direction; and
a pair of connection sidewalls that are adjoined to vertically-extending edges of recessed pillar sidewall and are parallel to the first horizontal direction.

4. The semiconductor structure of claim 3, wherein:
the alternating stacks are located on a top surface of a semiconductor material layer;
bottom edges of the laterally-recessed pillar sidewalls of the vertically-extending grooves are located within a horizontal plane including the top surface of the semiconductor material layer;
bottom edges of the connection sidewalls of the vertically-extending grooves are located within the horizontal plane;
bottom surfaces of the uniform width regions are located below the horizontal plane;
bottom surfaces of the laterally-bulging portions are located below the horizontal plane; and
each of the cavity-containing dielectric pillar structures comprises a first bottom surface located within the horizontal plane and further comprises a cylindrical downward-protruding stub portion that protrudes downward from a periphery of an opening in the first bottom surface into the semiconductor material layer.

5. The semiconductor structure of claim 1, wherein each of the alternating stacks comprises, from bottom to top:
a first vertically alternating sequence of first-tier insulating layers and first-tier electrically conductive layers; and
a second vertically alternating sequence of second-tier insulating layers and second-tier electrically conductive layers that overlie the first vertically alternating sequence.

6. The semiconductor structure of claim 1, wherein:
a first insulating cap layer that is thicker than any of the first-tier insulating layers and the second-tier insulating layers continuously extends over multiple first vertically alternating sequences of multiple alternating stacks, and below multiple second vertically alternating sequences of the multiple alternating stacks;
a second insulating cap layer that is thicker than any of the first-tier insulating layers and the second-tier insulating layers continuously extends over the multiple second vertically alternating sequences of the multiple alternating stacks;
portions of the first and the second insulating cap layers which extend through the lateral isolation trenches comprise at least portions of trench bridges.

7. The semiconductor structure of claim 6, wherein:
the first insulating cap layer comprises a two-dimensional array of first cylindrical openings through which the cavity-containing dielectric pillar structures vertically extend; and
the second insulating cap layer comprises a two-dimensional array of second cylindrical openings through which the cavity-containing dielectric pillar structures vertically extend.

8. The semiconductor structure of claim 7, wherein:
the first insulating cap layer comprises a two-dimensional array of first rectangular openings through which lateral isolation trench fill structures extend; and
the second insulating cap layer comprises a two-dimensional array of second rectangular openings through which the lateral isolation trench fill structures vertically extend.

9. The semiconductor structure of claim 6, wherein:
each of the cavity-containing dielectric pillar structures has a respective first neck portion at a level of the first insulating cap layer, and has a respective second neck portion at a level of the second insulating cap layer; and
each of the cavity-containing dielectric pillar structures comprises a first-tier pillar structure that vertically extends through a respective first vertically alternating sequence and a second-tier pillar structure that vertically extends through a respective second vertically alternating sequence.

10. The semiconductor structure of claim 9, wherein the respective first neck portion and the respective second neck portion are laterally spaced from a pair of most proximal lateral isolation trench fill structures by a respective lateral spacing.

11. The semiconductor structure of claim 6, wherein:
the first insulating cap layer has a first planar-region thickness over each of the first vertically alternating sequences and has a first pillar-region thickness over each of the first-tier pillar structures; and
the first planar-region thickness is greater than any vertical thickness of any of the first-tier insulating layers and is greater than the first pillar-region thickness.

12. The semiconductor structure of claim 6, wherein:
the alternating stack further comprises stepped surfaces;
at least one retro-stepped dielectric material portion is located over the stepped surfaces;
an upper part of at least one of the trench bridges comprises a part of the at least one retro-stepped dielectric material portion which extends through one of the lateral isolation trenches; and
a lower part of the at least one of the trench bridges comprises a portion of the first insulating cap layer which extends through the one of the lateral isolation trenches.

13. The semiconductor structure of claim 1, wherein the respective cavity-containing dielectric pillar structure comprises a respective plurality of the cylindrical encapsulated cavities that are vertically stacked and interconnected to each other by at least one vertically-extending seam that is embedded within the respective cavity-containing dielectric pillar structure.

14. The semiconductor structure of claim 2, further comprising:
first-type dielectric pillar structures vertically extending through a respective one of the alternating stacks, laterally spaced from the cavity-containing dielectric pillar structures and the lateral isolation trench fill structures, and comprising a respective cylindrical surface segment in direct contact with the respective one of the alternating stacks; and
second-type dielectric pillar structures comprising a respective first cylindrical arc surface segment contacting a respective one the alternating stacks and a respective second cylindrical arc surface segment contacting a respective silicon oxide liner that contacts a respective one of the cavity-containing dielectric pillar structures.

15. The semiconductor structure of claim 14, wherein each encapsulated cavity within the cavity-containing dielectric pillar structures has a horizontal cross-sectional shape that includes a plurality of concave sidewalls adjacent to the first-type dielectric pillar structures, a plurality of convex sidewalls between the first-type dielectric pillar structures, and two convex sidewalls extending substantially along the second horizontal direction adjacent to the lateral isolation trench fill structures.

16. A method of forming a semiconductor structure, comprising:
forming at least one vertically alternating sequence of continuous insulating layers and continuous sacrificial material layers;
forming lateral isolation trenches and isolation openings though the at least one vertically alternating sequence;
forming sets of isolation-region sacrificial fill material portions in the at least one vertically alternating sequence, wherein each set of isolation-region sacrificial fill material portions comprises a laterally alternating sequence of sacrificial wall structures formed in the lateral isolation trenches, and sacrificial isolation opening fill structures formed in the isolation openings that alternate along a first horizontal direction;
forming memory openings through the at least one vertically alternating sequence;
forming memory opening fill structures in the memory openings, wherein each of the memory opening fill structures comprises a respective vertical semiconductor channel and a respective vertical stack of memory elements;
removing the sacrificial isolation opening fill structures to reopen the isolation openings;
laterally-expanding the isolation openings by isotropically recessing proximal portions of the continuous sacrificial material layers and proximal portions of the continuous insulating layers, such that combination of the laterally-expanded isolation openings and the sacrificial wall structures divide the at least one vertically alternating sequence into alternating stacks of insulating layers and sacrificial material layers that are laterally spaced apart from each other along a second horizontal direction;
depositing a dielectric fill material at least in a peripheral portion of the laterally-expanded isolation openings; and
replacing the sacrificial material layers with electrically conductive layers.

17. The method of claim 16, wherein the isolation openings are laterally extended by:
performing a first isotropic etch process that etches a material of the continuous sacrificial material layers selectively to a material of the continuous insulating layers and selectively to a material of the sacrificial wall structures; and
performing a second isotropic etch process that etches the material of the continuous insulating layers selectively to the material of the sacrificial wall structures.

18. The method of claim 17, wherein:
the at least one vertically alternating sequence comprises a first-tier vertically alternating sequence of first continuous insulating layers and first continuous sacrificial material layers and a second-tier vertically alternating sequence of second continuous insulating layers and second continuous sacrificial material layers;
the method further comprises forming a first insulating cap layer between the first-tier vertically alternating sequence and the second-tier vertically alternating sequence, and forming a second insulating cap layer over the second-tier vertically alternating sequence;
the first insulating cap layer and the second insulating cap layer have a same material composition as the first continuous insulating layers and second continuous insulating layers; and
an etch distance of the second isotropic etch process for the material of the continuous insulating layers is greater than one half of a thickness of each of the continuous insulating layers, and is less than one half of a thickness of the first insulating cap layer and is less than one half of a thickness of the second insulating cap layer.

19. The method of claim 18, wherein portions of the first and the second insulating cap layer which extend through the lateral isolation trenches after the step of forming the lateral isolation trenches comprise at least portions of trench bridges.

20. The method of claim 16, further comprising forming cavity-containing dielectric pillar structures within the laterally-expanded isolation openings, wherein each of the cavity-containing dielectric pillar structures comprises a respective plurality of cylindrical encapsulated cavities that are vertically stacked and interconnected to each other by at least one vertically-extending seam that is embedded within a respective one of the cavity-containing dielectric pillar structures.
